(19) United States
(12) Patent Application Publication
(10) Pub. No.: US 2026/0206574 A1
(43) Pub. Date: Jul. 16, 2026

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Gilsung LEE, Suwon-si (KR); Seung-Jun LEE, Suwon-si (KR); Youngwoo KIM, Suwon-si (KR); Jae-Joo SHIM, Suwon-si (KR)

(73) Assignee: Samsung Electronics Co., Ltd., Suwon-si (KR)

(21) Appl. No.: 19/266,279

(22) Filed: Jul. 11, 2025

(30) Foreign Application Priority Data
Jan. 13, 2025 (KR) 10-2025-0005050

(51) Int. Cl. H01L 23/528; H01L 23/00; H01L 23/31; H01L 25/18; H10B 41/10; H10B 41/27; H10B 43/10; H10B 43/27; H10B 80/00; H10D 80/30

(52) U.S. Cl. CPC H10W 20/43; H10B 41/27; H10B 43/27; H10B 80/00; H10D 80/30; H10W 20/435; H10W 90/00; H10B 41/10; H10B 43/10; H10W 72/865; H10W 72/884; H10W 74/114; H10W 90/20; H10W 90/24; H10W 90/732; H10W 90/734; H10W 90/752; H10W 90/754

(57) ABSTRACT

A semiconductor device comprises a first conductive pattern, a second conductive pattern spaced apart in a first direction from the first conductive pattern, a dielectric pattern between the first and second conductive patterns, a first mold pattern at a same level as that of the first conductive pattern, a second mold pattern at a same level as that of the second conductive pattern and spaced apart in the first direction from the first mold pattern, a memory channel structure penetrating the first and second conductive patterns, a first connection contact electrically connected to the first conductive pattern, and a first connection contact dielectric layer surrounding the first connection contact. The dielectric pattern is between the first and second mold patterns. The first connection contact and the first connection contact dielectric layer are between the second conductive pattern and the second mold pattern.

### CROSS-REFERENCE TO RELATED APPLICATION

This application claims priority under 35 U.S.C § 119 to Korean Patent Application No. 10-2025-0005050 filed on Jan. 13, 2025 in the Korean Intellectual Property Office, the disclosure of which is hereby incorporated by reference in its entirety.

### BACKGROUND

Some example embodiments relate to a semiconductor device and/or an electronic system including the same, and more particularly, to a semiconductor device including a mold pattern and/or an electronic system including the same.

A semiconductor device attracts attention as an essential element in electronic industry because of its properties such as compactness, multi-functionality, and/or low manufacturing cost. Semiconductor devices may encompass one or more of semiconductor memory devices storing logic data, semiconductor logic devices processing operations of logic data, and hybrid semiconductor devices having both memory and logic elements.

Recently, high speed and/or low consumption of electronic products require that semiconductor devices embedded in the electronic products should have high operating speed and/or lower operating voltage. However, an increase in integration of semiconductor devices may cause a reduction in electrical properties and production yield of semiconductor devices. Therefore, many studies have been conducted to increase electrical properties and production yield of semiconductor devices.

### SUMMARY

Some example embodiments provide a semiconductor device with increased reliability and improved electrical properties and an electronic system including the same.

According to some example embodiments, a semiconductor device may comprise: a first conductive pattern; a second conductive pattern spaced apart in a first direction from the first conductive pattern; a dielectric pattern between the first conductive pattern and the second conductive pattern; a first mold pattern at a same level as a level of the first conductive pattern; a second mold pattern at same level as a level of the second conductive pattern and spaced apart in the first direction from the first mold pattern; a memory channel structure penetrating the first conductive pattern and the second conductive pattern; a first connection contact electrically connected to the first conductive pattern; and a first connection contact dielectric layer that surrounds the first connection contact. The dielectric pattern may be between the first mold pattern and the second mold pattern. The first connection contact and the first connection contact dielectric layer may be between the second conductive pattern and the second mold pattern.

Alternatively or additionally according to some example embodiments, a semiconductor device may comprise: a first side separation structure; a second side separation structure spaced apart in a first direction from the first side separation structure; a first conductive pattern, a second conductive pattern, and a mold pattern between the first side separation structure and the second side separation structure; a dielectric structure between the first side separation structure and the second side separation structure, the dielectric structure penetrating the mold pattern; a memory channel structure penetrating the first conductive pattern; and a first connection contact electrically connected to the first conductive pattern. The first conductive pattern may be between the first side separation structure and the dielectric structure. The second conductive pattern may be between the second side separation structure and the dielectric structure. The first conductive pattern and the second conductive pattern may be spaced apart in the first direction from each other. The mold pattern may contact the first conductive pattern and the second conductive pattern. The mold pattern may comprise: a first part between the dielectric structure and the first conductive pattern; a second part between the dielectric structure and the second conductive pattern; and a third part that connects the first part and the second part to each other.

Alternatively or additionally according to some example embodiments, an electronic system may comprise: a main board; a semiconductor device on the main board; and a controller on the main board and electrically connected to the semiconductor device. The semiconductor device may comprise: a first side separation structure; a second side separation structure spaced apart in a first direction from the first side separation structure; a first conductive pattern, a second conductive pattern, a third conductive pattern, a fourth conductive pattern, a first mold pattern, and a second mold pattern between the first side separation structure and the second side separation structure; a dielectric pattern between the first and third conductive patterns, between the second and fourth conductive patterns, and between the first and second mold patterns; a dielectric structure between the first and second side separation structures, the dielectric structure penetrating the first and second mold structures; a memory channel structure that penetrates the first conductive pattern; a first connection contact electrically connected to the first conductive pattern; a first connection contact dielectric layer surrounding the first connection contact; a second connection contact electrically connected to the third conductive pattern; and a second connection contact dielectric layer surrounding the second connection contact. The first mold pattern may contact the first conductive pattern and the second conductive pattern. The second mold pattern may contact the third conductive pattern and the fourth conductive pattern. The first connection contact may contact the first conductive pattern and the first mold pattern. The first connection contact dielectric layer may contact the third conductive pattern and the second mold pattern.

Alternatively or additionally according to some example embodiments, there is provided a method of fabricating a semiconductor device comprising fabricating a peripheral circuit on and in a substrate, forming a plurality of source layers and a plurality of dummy layers on the peripheral circuit, forming a plurality of dielectric patterns and a plurality of sacrificial patterns on the plurality of source layers and the plurality of dummy layers, forming a plurality of holes through the plurality of dielectric patterns and the plurality of sacrificial patterns, filling the plurality of holes with a sacrificial layer, forming a photoresist layer on a topmost one of the plurality of dielectric patterns, the photoresist layer defining an opening over at least some of the plurality of the filled plurality of holes, removing at least some of the sacrificial layer, and expanding the at least some of the plurality of holes from which the sacrificial layer is removed.

In some example embodiments, the expanding the at least some of the plurality of holes includes isotropically etching the holes.

In some example embodiments, the expanding includes expanding with a wet etching process.

### BRIEF DESCRIPTION OF DRAWINGS

FIG. 1A illustrates a simplified block diagram showing an electronic system including a semiconductor device according to some example embodiments.

FIG. 1B illustrates a simplified perspective view showing an electronic system including a semiconductor device according to some example embodiments.

FIGS. 1C and 1D illustrate simplified cross-sectional views showing a semiconductor package according to some example embodiments.

FIG. 2A illustrates a plan view showing a semiconductor device according to some example embodiments.

FIG. 2B illustrates a cross-sectional view taken along line A1-A1′ of FIG. 2A.

FIG. 2C illustrates a cross-sectional view taken along line A2-A2′ of FIG. 2A.

FIG. 2D illustrates a cross-sectional view taken along line A3-A3′ of FIG. 2A.

FIG. 2E illustrates an enlarged view showing section Q1 of FIG. 2A.

FIG. 2F illustrates an enlarged view showing section Q2 of FIG. 2B.

FIG. 2G illustrates an enlarged view showing section Q3 of FIG. 2C.

FIGS. 3A, 3B, 3C, 4A, 4B, 5A, 5B, 6A, 6B, 6C, 7A, 7B, 7C, 8A, and 8B illustrate diagrams showing a method of fabricating a semiconductor device depicted in FIGS. 2A to 2G.

FIG. 9 illustrates a plan view showing a semiconductor device according to some example embodiments.

FIGS. 10 and 11 illustrate diagrams showing a method of fabricating a semiconductor device depicted in FIG. 9.

FIG. 12 illustrates a plan view showing a semiconductor device according to some example embodiments.

FIG. 13 illustrates a plan view showing a method of fabricating a semiconductor device depicted in FIG. 12.

FIG. 14 illustrates an enlarged plan view showing a semiconductor device according to some example embodiments.

FIGS. 15, 16, and 17 illustrate plan views showing a method of fabricating a semiconductor device depicted in FIG. 14.

FIGS. 18A and 18B illustrate cross-sectional views showing a semiconductor device according to some example embodiments.

### DETAILED DESCRIPTION OF EXAMPLE EMBODIMENTS

With reference to the accompanying drawings, the following will describe in detail a semiconductor device and an electronic system including the same according to some example embodiments.

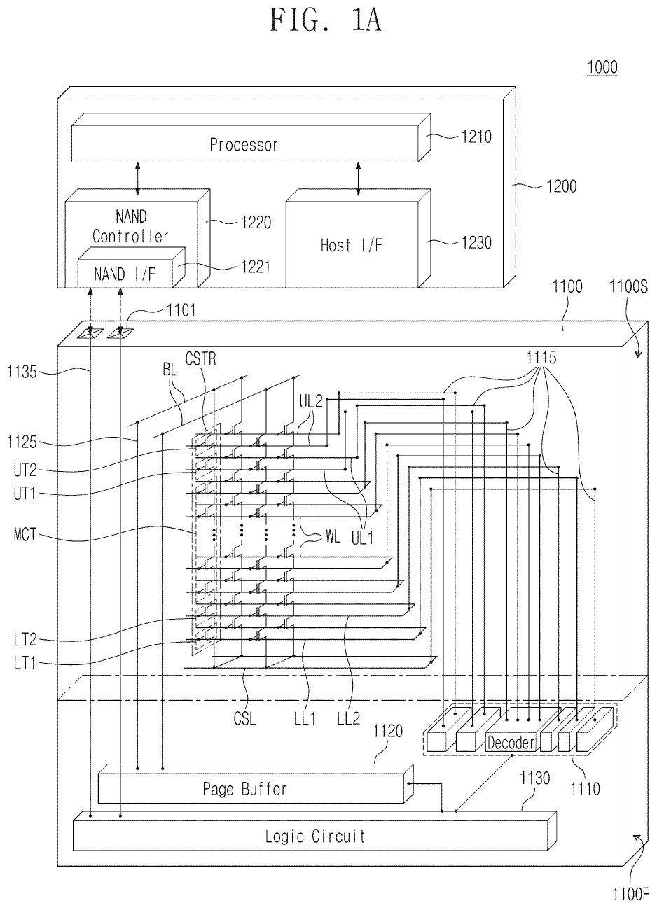

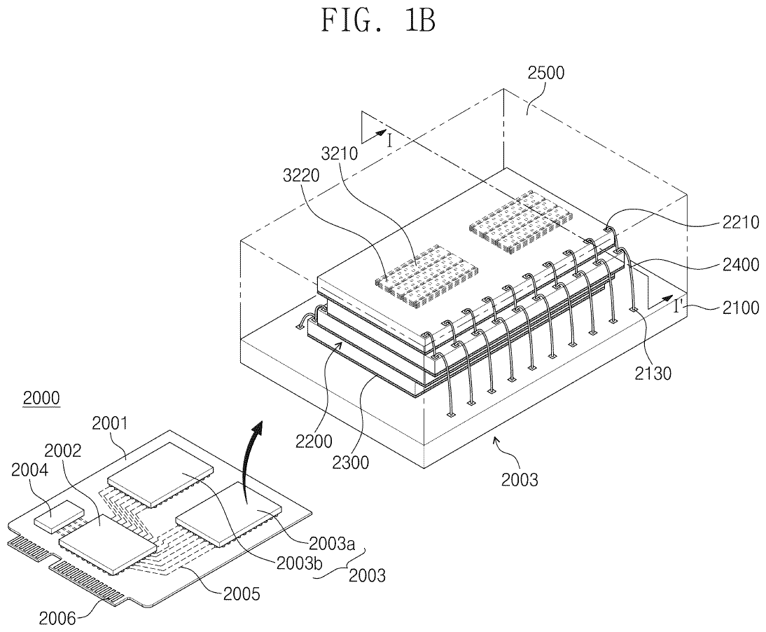

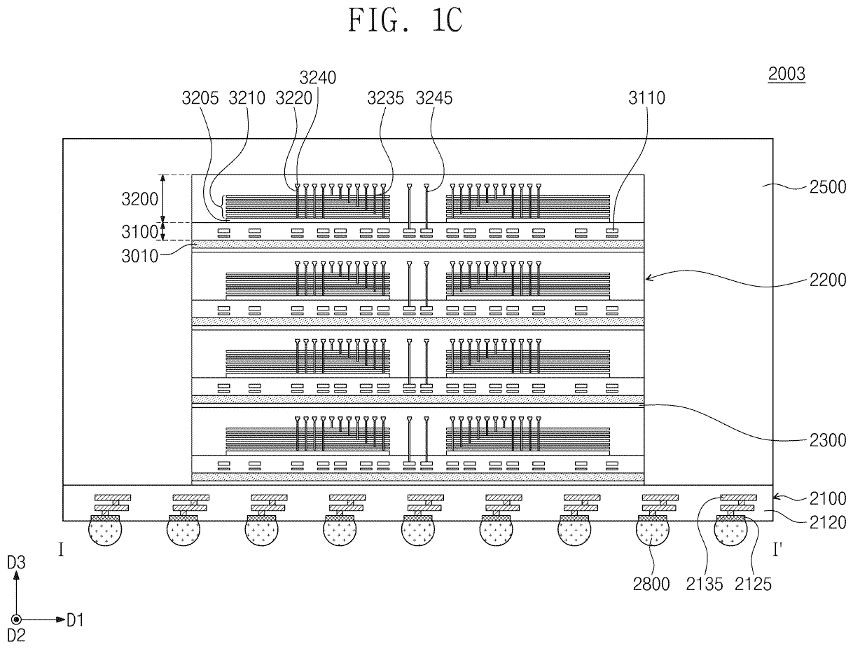

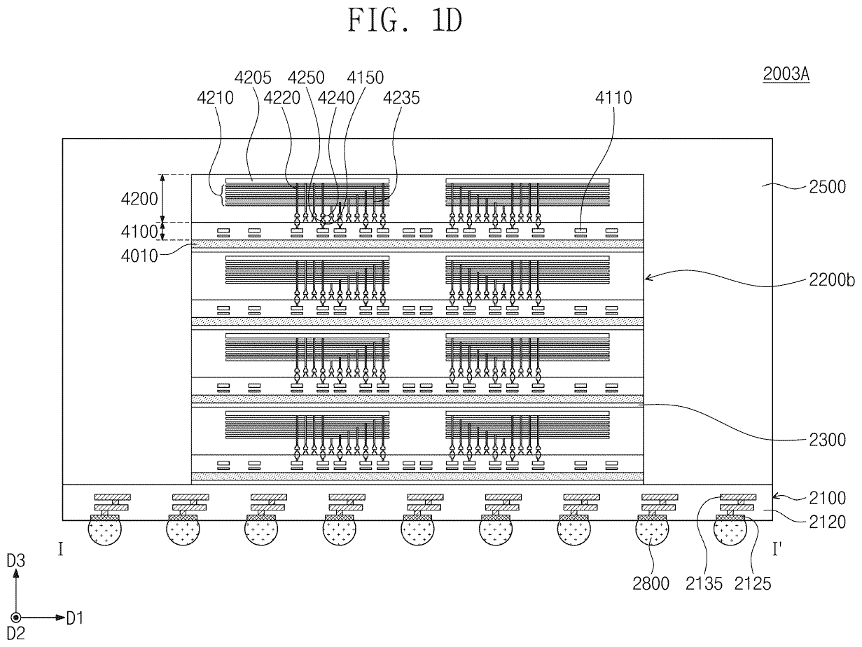

FIG. 1A illustrates a simplified block diagram showing an electronic system including a semiconductor device according to some example embodiments.

Referring to FIG. 1A, an electronic system 1000 according to some example embodiments may include a semiconductor device 1100 and a controller 1200 electrically connected to the semiconductor device 1100. The electronic system 1000 may be, may include, or may be included a storage device that includes a single or a plurality of semiconductor devices 1100, and/or may be, may include, or may be included an electronic device that includes the storage device. For example, the electronic system 1000 may be, may include, or may be included in a solid state drive (SSD) device, a universal serial bus (USB), a computing system, a medical apparatus, or a communication apparatus, each of which includes a single or a plurality of semiconductor devices 1100.

The semiconductor device 1100 may be or may include a nonvolatile memory device, such as a NAND Flash memory device. The semiconductor device 1100 may include a first structure 1100F and a second structure 1100S on the first structure 1100F. In some example embodiments, the first structure 1100F may be disposed on a side of the second structure 1100S. The first structure 1100F may be or may include a peripheral circuit structure that includes a decoder circuit 1110, a page buffer 1120, and a logic circuit 1130. The second structure 1100S may be or may include a memory cell structure that includes a bit line BL, a common source line CSL, word lines WL, first and second gate upper lines UL1 and UL2, first and second gate lower lines LL1 and LL2, and memory cell strings CSTR between the bit line BL and the common source line CSL. In some example, embodiments, the semiconductor device 1100 may have a cell-on-periphery (COP) structure; example embodiments are not limited thereto.

In the second structure 1100S, each of the memory cell strings CSTR may include lower transistors LT1 and LT2 adjacent to the common source line CSL, upper transistors UT1 and UT2 adjacent to the bit line BL, and memory cell transistors MCT disposed between the lower transistors LT1 and LT2 and the upper transistors UT1 and UT2. The number of the lower transistors LT1 and LT2 and/or the number of the upper transistors UT1 and UT2 may be variously changed in accordance with example embodiments, and may or may not be the same.

In some example embodiments, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 that extend from the first structure 1100F to the second structure 1100S. The bit lines BL may be electrically connected to the page buffer 1120 through second connection lines 1125 that extend from the first structure 1100F to the second structure 1100S.

In the first structure 1100F, the decoder circuit 1110 and the page buffer 1120 may perform a control operation on at least one selection memory cell transistor among the plurality of memory cell transistors MCT. The logic circuit 1130 may control the decoder circuit 1110 and the page buffer 1120. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135 that extends from the first structure 1100F to the second structure 1100S.

The controller 1200 may include a processor 1210, a NAND controller 1220, and a host interface 1230. In some example embodiments, the electronic system 1000 may include a plurality of semiconductor devices 1100, and in this case, the controller 1200 may control the plurality of semiconductor devices 1100.

The processor 1210 may control some or all, e.g., an overall operation of the electronic system 1000 that includes the controller 1200. The processor 1210 may operate based on firmware, such as fetched firmware, dynamically determined firmware, or, alternatively predetermined firmware, and may control the NAND controller 1220 to access the semiconductor device 1100. The NAND controller 1220 may include a NAND interface 1221 that processes communication with the semiconductor device 1100. The NAND interface 1221 may be used to transfer therethrough a control command to control the semiconductor device 1100, data intended to be written on the memory cell transistors MCT of the semiconductor device 1100, and/or data intended to be read from the memory cell transistors MCT of the semiconductor device 1100. The host interface 1230 may provide the electronic system 1000 with communication with an external host. When a control command is received through the host interface 1230 from an external host, the semiconductor device 1100 may be controlled by the processor 1210 in response to the control command.

FIG. 1B illustrates a simplified perspective view showing an electronic system including a semiconductor device according to some example embodiments.

Referring to FIG. 1B, an electronic system 2000 according to some example embodiments may include a main board 2001, a controller 2002 mounted on the main board 2001, at least one semiconductor package 2003, and a dynamic random access memory (DRAM) 2004. The semiconductor package 2003 and the DRAM 2004 may be connected to the controller 2002 through wiring patterns 2005 formed on the main board 2001.

The main board 2001 may include a connector 2006 including a plurality of pins which will be connected to an external host. The number and/or the arrangement of the plurality of pins on the connector 2006 may be changed based on a communication interface between the electronic system 2000 and the external host. In some example embodiments, the electronic system 2000 may communicate with the external host through one or more interfaces, for example, through one or more of universal serial bus (USB), peripheral component interconnect express (PIC-Express), serial advanced technology attachment (SATA), and/or M-PHY for universal flash storage (UFS). In some example embodiments, the electronic system 2000 may operate with power supplied through the connector 2006 from an external host. The electronic system 2000 may further include a power management integrated circuit (PMIC) by which the power supplied from the external host is distributed to the controller 2002 and the semiconductor package 2003.

The controller 2002 may write data to the semiconductor package 2003, may read data from the semiconductor package 2003, and/or may increase an operating speed of the electronic system 2000.

The DRAM 2004 may be or may include a buffer memory that reduces a difference in speed between the external host and the semiconductor package 2003 that serves as a data storage space. The DRAM 2004 included in the electronic system 2000 may operate as a kind of cache memory, and may provide a space for temporary data storage in a control operation of the semiconductor package 2003. When the DRAM 2004 is included in the electronic system 2000, the controller 2002 may include not only a NAND controller for controlling the semiconductor package 2003, but also a DRAM controller for controlling the DRAM 2004; example embodiments are not limited thereto.

The semiconductor package 2003 may include first and second semiconductor packages 2003a and 2003b that are spaced apart from each other. Each of the first and second semiconductor packages 2003a and 2003b may be or may include a semiconductor package including a plurality of semiconductor chips 2200. Each of the first and second semiconductor packages 2003a and 2003b may include a package substrate 2100, semiconductor chips 2200 on the package substrate 2100, adhesion layers 2300 disposed on bottom surfaces of the semiconductor chips 2200, connection structures 2400 that electrically connect the semiconductor chips 2200 to the package substrate 2100, and a mold layer 2500 on the package substrate 2100 and covering the semiconductor chips 2200 and the connection structures 2400.

The package substrate 2100 may be or may include an integrated circuit board including package upper pads 2130. Each of the semiconductor chips 2200 may include one or more input/output pads 2210. The input/output pad 2210 may correspond to the input/output pad 1101 of FIG. 1A. Each of the semiconductor chips 2200 may include gate stack structures 3210 and memory channel structures 3220. Each of the semiconductor chips 2200 may include a semiconductor device which will be discussed below.

In some example embodiments, the connection structures 2400 may be or may include bonding wires that electrically connect the input/output pads 2210 to the package upper pads 2130. Therefore, in each of the first and second semiconductor packages 2003a and 2003b, the semiconductor chips 2200 may be electrically connected to each other in a wire bonding manner, and may be electrically connected to the package upper pads 2130 of the package substrate 2100. In some example embodiments, in each of the first and second semiconductor packages 2003a and 2003b, the semiconductor chips 2200 may be electrically connected to each other using through-silicon vias (TSVs) instead of or in addition to the connection structures 2400 or the bonding wires.

In some example embodiments, the controller 2002 and the semiconductor chips 2200 may be included in one package. In some example embodiments, the controller 2002 and the semiconductor chips 2200 may be mounted on a separate interposer substrate other than the main board 2001, and may be connected to each other through connection lines provided in the interposer substrate.

FIGS. 1C and 1D illustrate simplified cross-sectional views showing a semiconductor package according to some example embodiments. FIGS. 1C and 1D each depicts an example of the semiconductor package 2003 shown in FIG. 1B, conceptually showing a section taken along line I-I′ of the semiconductor package 2003 shown in FIG. 1B.

Referring to FIG. 1C, a printed circuit board may be used as the package substrate 2100 of the semiconductor package 2003. The package substrate 2100 may include a package substrate body 2120, package upper pads (see 2130 of FIG. 1B) disposed on a top surface of the package substrate body 2120, lower pads 2125 disposed or exposed on a bottom surface of the package substrate body 2120, and internal lines 2135 that lie in the package substrate body 2120 and electrically connect the upper pads 2130 to the lower pads 2125. A number of and/or an arrangement of internal lines 2135 is not limited to features described within the figures. The upper pads 2130 may be electrically connected to connection structures (see 2400 of FIG. 1B). The lower pads 2125 may be connected through conductive connectors 2800 to the wiring patterns 2005 on the main board 2001 of the electronic system 2000, as shown in FIG. 1B.

Each of the semiconductor chips 2200 may include a semiconductor substrate 3010, and may also include a first structure 3100 and a second structure 3200 that are sequentially stacked on the semiconductor substrate 3010. A thickness of and/or a material composition of the first structure 3100 may be the same for different ones of the semiconductor chips 2200, or at least one of a thickness of and/or a material composition of at least one of the semiconductor chips 2200 may be different from others of the semiconductor chips 2200. The first structure 3100 may include a peripheral circuit region including peripheral wiring lines 3110. The second structure 3200 may include a common source line 3205, a gate stack structure 3210 on the common source line 3205, memory channel structures 3220 that penetrate the gate stack structure 3210, bit lines 3240 electrically connected to the memory channel structures 3220, and gate contact plugs 3235 electrically connected to corresponding word lines (see WL of FIG. 1A) of the gate stack structure 3210.

Each of the semiconductor chips 2200 may include through wiring lines 3245 that are electrically connected to the peripheral wiring lines 3110 of the first structure 3100 and that extend into the second structure 3200. A number of and/or an arrangement of peripheral wiring lines 3110 are not limited to features described within the figures. The through wiring line 3245 may be disposed outside the gate stack structure 3210. In some example embodiments, the through wiring line 3245 may penetrate the gate stack structure 3210. Each of the semiconductor chips 2200 may further include an input/output pad (see 2210 of FIG. 1B).

Referring to FIG. 1D, in a semiconductor package 2003A, each of semiconductor chips 2200b may include a semiconductor substrate 4010, a first structure 4100 on the semiconductor substrate 4010, and a second structure 4200 provided on and wafer-bonded to the first structure 4100.

The first structure 4100 may include a peripheral circuit region including a peripheral wiring line 4110 and first bonding structures 4150. The second structure 4200 may include a common source line 4205, a gate stack structure 4210 between the common source line 4205 and the first structure 4100, memory channel structures 4220 that penetrate the gate stack structure 4210, bit lines 4240 electrically connected to the memory channel structures 4220, gate contact plugs 4235 electrically connected to corresponding word lines (see WL of FIG. 1A) of the gate stack structure 4210, and second bonding structures 4250. For example, the second bonding structures 4250 may be electrically connected to corresponding memory channel structures 4220 through the bit lines 4240 electrically connected to the memory channel structures 4220. The first bonding structures 4150 of the first structure 4100 may be bonded to the second bonding structures 4250 of the second structure 4200. The first and second bonding structures 4150 and 4250 may have their bonding portions formed of, for example, copper (Cu). Each of the semiconductor chips 2200b or at least one of the semiconductor chips 2200b may further include an input/output pad (see 2210 of FIG. 1B).

The semiconductor chips 2200 of FIG. 1C and/or the semiconductor chips 2200b of FIG. 1D may be electrically connected to each other through the connection structures (see 2400 of FIG. 1B) shaped like bonding wires. In some example embodiments, semiconductor chips, such as the semiconductor chips 2200 of FIG. 1C and the semiconductor chips 2200b of FIG. 1D, in one semiconductor package may be electrically connected through connection structures including through electrodes (TSV).

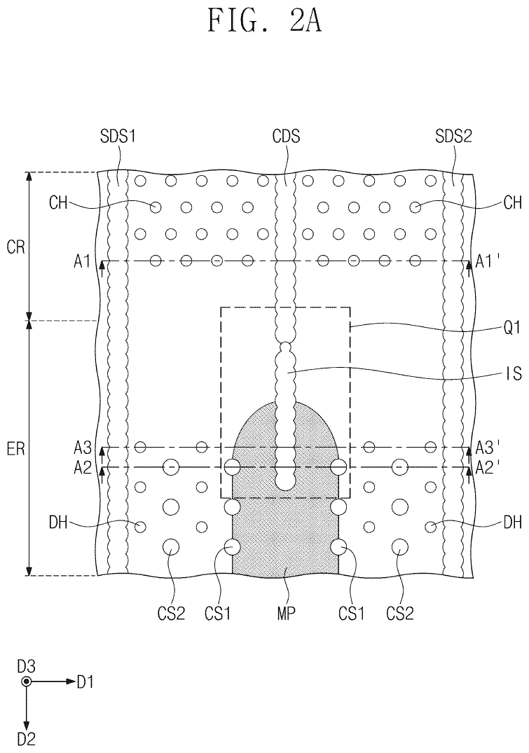

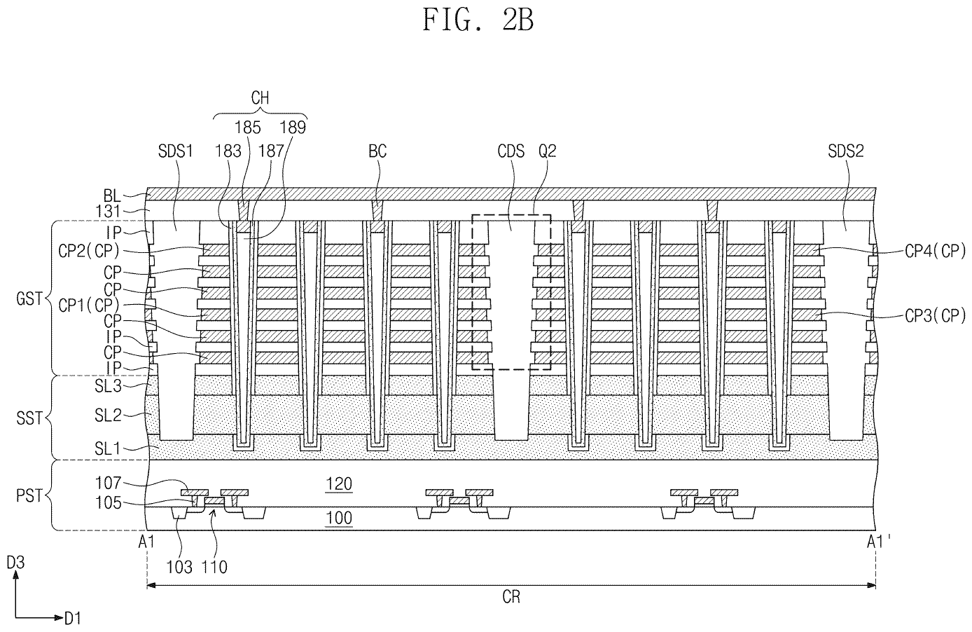

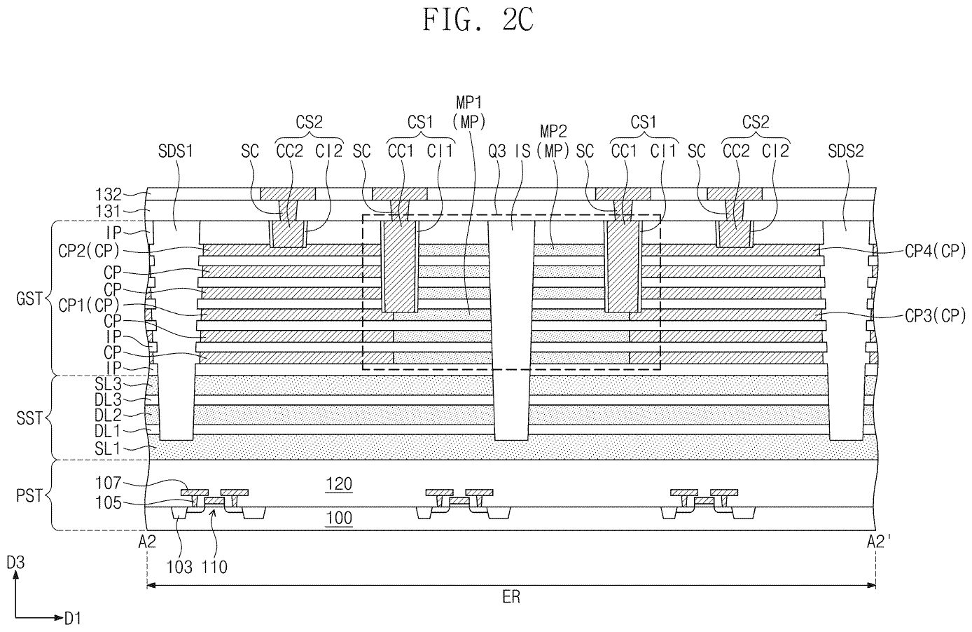

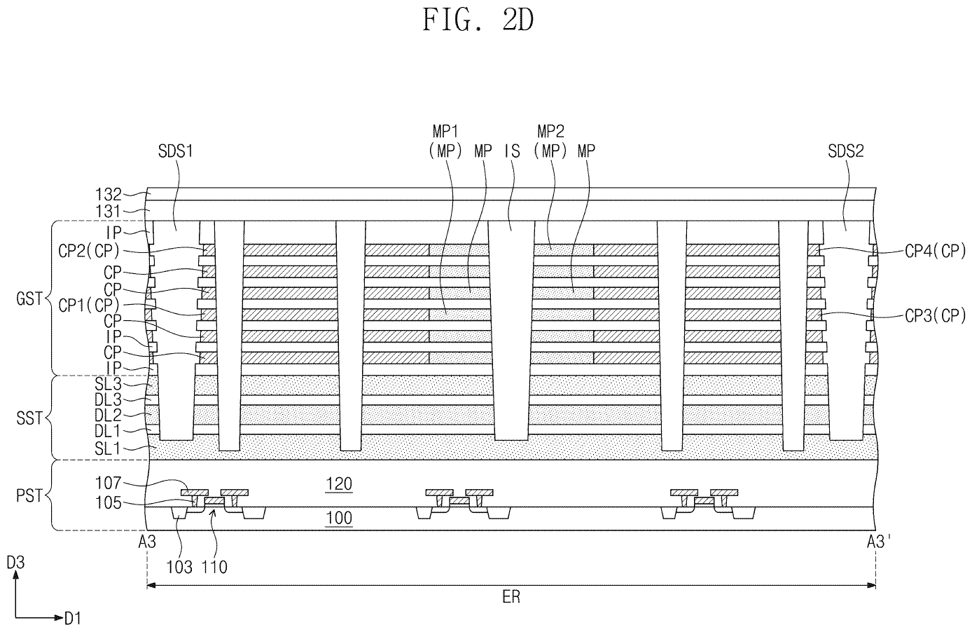

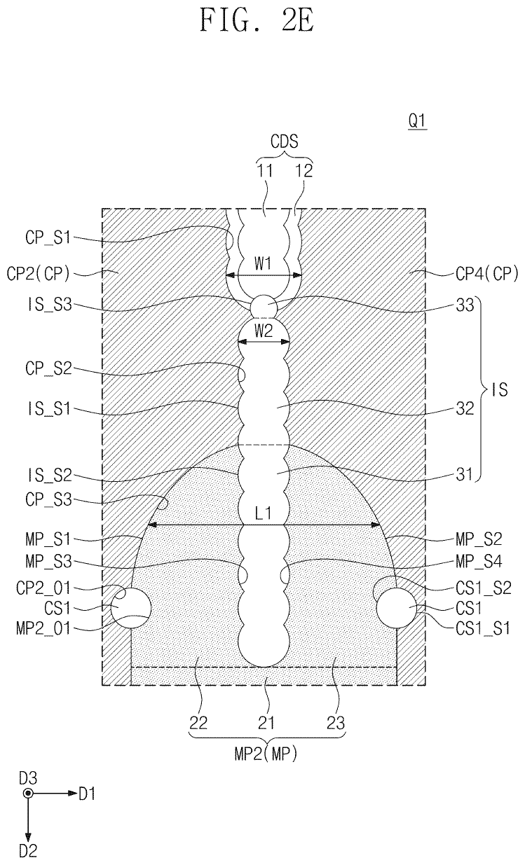

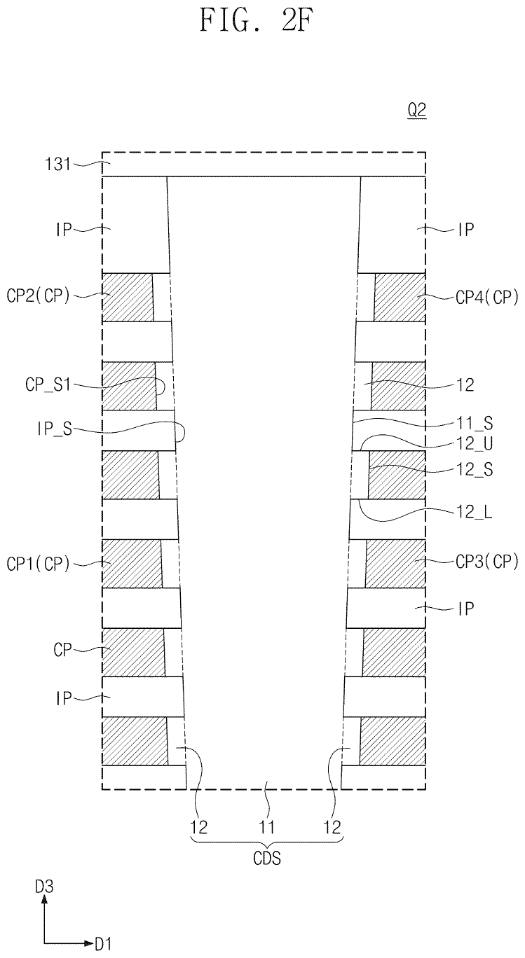

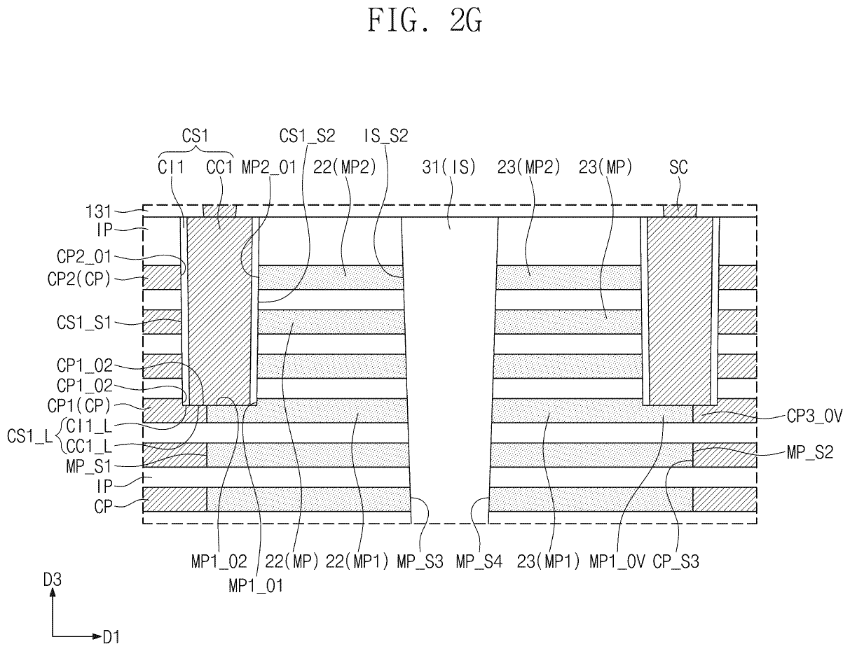

FIG. 2A illustrates a plan view showing a semiconductor device according to some example embodiments. FIG. 2B illustrates a cross-sectional view taken along line A1-A1′ of FIG. 2A. FIG. 2C illustrates a cross-sectional view taken along line A2-A2′ of FIG. 2A. FIG. 2D illustrates a cross-sectional view taken along line A3-A3′ of FIG. 2A. FIG. 2E illustrates an enlarged view showing section Q1 of FIG. 2A. FIG. 2F illustrates an enlarged view showing section Q2 of FIG. 2B. FIG. 2G illustrates an enlarged view showing section Q3 of FIG. 2C.

Referring to FIGS. 2A, 2B, 2C, and 2D, a semiconductor device may include a peripheral circuit structure PST and a memory cell structure on the peripheral circuit structure PST. In some example embodiments, the semiconductor device may have a cell-on-periphery or cell-over-periphery (COP) structure; example embodiments are not limited thereto. The memory cell structure may include a source structure SST and a gate stack structure GST on the source structure SST.

The peripheral circuit structure PST may include a substrate 100. The substrate 100 may be or may include one or more of a semiconductor substrate, a dielectric substrate, or a semiconductor-on-insulator (SOI) substrate. The semiconductor substrate may be or include, for example, a silicon substrate and/or a germanium substrate. The substrate 100 may have a plate shape elongated along a plane defined in a first direction D1 and a second direction D2. The first direction D1 and the second direction D2 may intersect each other. For example, the first direction D1 and the second direction D2 may be horizontal directions that are orthogonal to each other.

The peripheral circuit structure PST may include a peripheral circuit dielectric layer 120 on the substrate 100. The peripheral circuit dielectric layer 120 may include a dielectric material. In some example embodiments, the peripheral circuit dielectric layer 120 may be or may include a multiple dielectric layer including a plurality of dielectric layers.

The substrate 100 may have device isolation layers 103 therein. The device isolation layers 103 may include a dielectric material. The peripheral circuit structure PST may further include transistors 110, such as but not limited to planar transistors. The transistors 110 may be provided between the substrate 100 and the peripheral circuit dielectric layer 120. The transistor 110 may include source/drain regions, a gate dielectric layer, and a gate electrode. The gate electrode may extend in a direction such as D2 and/or a direction such as D1; example embodiments are not limited thereto.

The peripheral circuit structure PST may further include peripheral contacts 105 and peripheral conductive lines 107. The peripheral contact 105 may be connected to the transistor 110. The peripheral conductive line 107 may be connected to the peripheral contact 105. The peripheral contact 105 and the peripheral conductive line 107 may include a conductive material. A number of and/or an arrangement of peripheral contacts 105 and/or peripheral conductive lines 107 are not limited to features described in the figures.

The memory cell structure may include a source structure SST, a gate stack structure GST, memory channel structures CH, a first cover dielectric layer 131, a second cover dielectric layer 132, a first side separation structure SDS1, a second side separation structure SDS2, a central separation structure CDS, a dielectric structure IS, first connection contact structures CS1, second connection contact structures CS2, bit-line contacts BC, bit lines BL, dummy structures DH, conductive line contacts SC, and conductive lines CL.

The source structure SST may include a cell region CR and an extension region ER. The cell region CR and the extension region ER may be distinguished from a planar perspective defined by the first direction D1 and the second direction D2.

The source structure SST may include a number of source layers and dummy layers such as a first source layer SL1 on the peripheral circuit structure PST, a second source layer SL2 on the first source layer SL1, a first dummy layer DL1, second dummy layer DL2, and a third dummy layer DL3 on the first source layer SL1, and a third source layer SL3 on the second source layer SL2 and the third dummy layer DL3.

The first, second, and third source layers SL1, SL2, and SL3 may include a conductive material, such as the same or different conductive material. For example, at least one of the first, second, and third source layers SL1, SL2, and SL3 may include polysilicon such as doped polysilicon. The second source layer SL2 may be disposed on the cell region CR. The second source layer SL2 may be a common source line.

The first dummy layer DL1, the second dummy layer DL2, and the third dummy layer DL3 may be sequentially provided along a third direction D3 on the first source layer SL1. The first, second, and third dummy layers DL1, DL2, and DL3 may be disposed on the extension region ER. The first, second, and third dummy layers DL1, DL2, and DL3 may be located at the same level as that of the second source layer SL2. The first, second, and third dummy layer DL1, DL2, and DL3 may include a dielectric material. In some example embodiments, the first and third dummy layers DL1 and DL3 may include the same dielectric material, and the second dummy layer DL2 may include a dielectric material different from that of the first and third dummy layers DL1 and DL3, e.g., having a different dielectric constant and/or a different etch rate. For example, the second dummy layer DL2 may include nitride, and the first and third dummy layers DL1 and DL3 may include oxide.

The gate stack structure GST may be provided on the source structure SST. In some example embodiments, the number of the gate stack structure GST may be two or more.

The gate stack structure GST may include dielectric patterns IP and conductive patterns CP that are alternately stacked along the third direction D3. The third direction D3 may intersect the first direction D1 and the second direction D2. For example, the third direction D3 may be a vertical direction perpendicular to the first direction D1 and the second direction D2.

The gate stack structure GST may further include mold patterns MP. The mold patterns MP may overlap each other in the third direction D3. The mold patterns MP may be spaced apart from each other in the third direction D3. The mold patterns MP and the dielectric patterns IP may be alternately stacked along the third direction D3. The mold pattern MP may be located at the same level as that of the conductive pattern CP. As used herein, the term “level” may refer to a distance in the third direction D3 from a top surface of the substrate 100. The mold pattern MP may be in contact with the conductive pattern CP.

The dielectric patterns IP may include a dielectric material. For example, the dielectric patterns IP may include oxide. The conductive patterns CP may include a conductive material. For example, the conductive patterns CP may include tungsten. The mold patterns MP may include a dielectric material different from that of the dielectric patterns IP, e.g., having a different dielectric constant and/or a different etch rate. For example, the mold patterns MP may include nitride.

The memory channel structures CH may extend in the third direction D3 to penetrate the conductive patterns CP and the dielectric patterns IP of the gate stack structure GST. The memory channel structures CH may penetrate the third source layer SL3 and the second source layer SL2. Each of the memory channel structures CH may include a dielectric capping layer 189, a channel layer 187 that surrounds the dielectric capping layer 189, and a memory layer 183 that surrounds the channel layer 187. The memory channel structures CH may be disposed on the cell region CR.

The dielectric capping layer 189 may include a dielectric material. For example, the dielectric capping layer 189 may include oxide. The channel layer 187 may include a conductive material. For example, the channel layer 187 may include polysilicon such as doped polysilicon. The channel layer 187 may be electrically connected to the second source layer SL2. The second source layer SL2 may penetrate the memory layer 183 to come into connection with the channel layer 187.

The memory layer 183 may store data. In some example embodiments, the memory layer 183 may include a tunnel dielectric layer that surrounds the channel layer 187, a data storage layer that surrounds the tunnel dielectric layer, and a blocking layer that surrounds the data storage layer. The tunnel dielectric layer and the blocking layer may include, for example, oxide such as silicon oxide, and may or may not include a nitride. The data storage layer may include, for example, nitride such as silicon nitride and may or may not include an oxide.

Each of the memory channel structures CH may further include a bit-line pad 185 provided on the channel layer 187. The bit-line pad 185 may include a conductive material. For example, the bit-line pad 185 may include polysilicon such as doped polysilicon and/or metal.

The dummy structures DH may extend in the third direction D3 to penetrate the conductive patterns CP and the dielectric patterns IP of the gate stack structure GST. The dummy structures DH may be disposed on the extension region ER. The dummy structures DH may include a dielectric material. In some example embodiments, the dummy structures DH may have a similar structure to that of the memory channel structure CH.

The first cover dielectric layer 131 may be provided on the gate stack structure GST and the memory channel structures CH. The first cover dielectric layer 131 may include a dielectric material. The second cover dielectric layer 132 may be provided on the first cover dielectric layer 131. The second cover dielectric layer 132 may include a dielectric material.

The first side separation structure SDS1, the second side separation structure SDS2, the central separation structure CDS, and the dielectric structure IS may penetrate in the third direction D3 through the gate stack structure GST. The first side separation structure SDS1, the second side separation structure SDS2, the central separation structure CDS, and the dielectric structure IS may penetrate in the third direction D3 through the conductive patterns CP and the dielectric patterns IP. The dielectric structure IS may penetrate in the third direction D3 through the mold patterns MP.

The first side separation structure SDS1, the second side separation structure SDS2, the central separation structure CDS, and the dielectric structure IS may extend in the second direction D2. A dielectric material may be included in the first side separation structure SDS1, the second side separation structure SDS2, the central separation structure CDS, and the dielectric structure IS. In some example embodiments, the dielectric structure IS may include the same dielectric material as that of the dielectric pattern IP. For example, the dielectric structure IS and the dielectric pattern IP may include oxide. Alternatively or additionally in some example embodiments, the dielectric structure IS may include a dielectric material different from those of the dielectric pattern IP and the mold pattern MP. For example, the dielectric structure IS may include a material having an etch selectivity (e.g., a slower etch rate and/or a faster etch rate) with respect to materials included in the dielectric pattern IP and the mold pattern MP.

The first side separation structure SDS1 and the second side separation structure SDS2 may be spaced apart from each other in the first direction D1. The first side separation structure SDS1 and the second side separation structure SDS2 may be provided therebetween with the central separation structure CDS, the dielectric structure IS, the conductive patterns CP, the dielectric patterns IP, and the mold patterns MP.

In some example embodiments, a region between the first side separation structure SDS1 and the central separation structure CDS may be defined a first block of the semiconductor device, and a region between the central separation structure CDS and the second side separation structure SDS2 may be defined as a second block of the semiconductor device.

In some example embodiments, a region between the first side separation structure SDS1 and the second side separation structure SDS2 may be defined as one block of the semiconductor device.

In some example embodiments, the semiconductor device may include a first side separation structure, a second side separation structure, and a third side separation structure that are sequentially arranged in the first direction D1. The semiconductor device may include a first central separation structure between the first and second side separation structures, a second central separation structure between the second and third side separation structures, a first dielectric structure between the first and second side separation structures, and a second dielectric structure between the second and third side separation structures. A region between the first side separation structure and the third side separation structure may be defined as one block of the semiconductor device.

In some example embodiments, the semiconductor device may include a first side separation structure, a second side separation structure, a third side separation structure, and a fourth side separation structure that are sequentially arranged in the first direction D1. The semiconductor device may include a first central separation structure between the first and second side separation structures, a second central separation structure between the second and third side separation structures, a third central separation structure between the third and fourth side separation structures, a first dielectric structure between the first and second side separation structures, a second dielectric structure between the second and third side separation structures, and a third dielectric structure between the third and fourth side separation structures. A region between the first side separation structure and the fourth side separation structure may be defined as one block of the semiconductor device. The bit-line contact BC may be connected to the memory channel structure CH. The bit-line contact BC may penetrate the first cover dielectric layer 131. The bit line BL may be provided on the bit-line contact BC. The bit line BL may be provided in the second cover dielectric layer 132.

The conductive line contact SC may be connected to the first connection contact structure CS1 or the second connection contact structure CS2. The conductive line contact SC may penetrate the first cover dielectric layer 131. The conductive line CL may be provided on the conductive line contact SC. The conductive line CL may be provided in the second cover dielectric layer 132. A conductive material may be included in the bit-line contact BC, the bit line BL, the conductive line contact SC, and the conductive line CL.

The conductive patterns CP may include a first conductive pattern CP1, a second conductive pattern CP2, a third conductive pattern CP3, and a fourth conductive pattern CP4. The first conductive pattern CP1 and the second conductive pattern CP2 may overlap each other in the third direction D3. The first conductive pattern CP1 and the second conductive pattern CP2 may be spaced apart from each other in the third direction D3. The second conductive pattern CP2 may be located at a higher level than that of the first conductive pattern CP1. The third conductive pattern CP3 and the fourth conductive pattern CP4 may overlap each other in the third direction D3. The third conductive pattern CP3 and the fourth conductive pattern CP4 may be spaced apart from each other in the third direction D3. The fourth conductive pattern CP4 may be located at a higher level than that of the third conductive pattern CP3. The first conductive pattern CP1 and the third conductive pattern CP3 may be located at the same level. The second conductive pattern CP2 and the fourth conductive pattern CP4 may be located at the same level.

The memory channel structure CH may penetrate in the third direction D3 through the first and second conductive patterns CP1 and CP2, or may penetrate in the third direction D3 through the third and fourth conductive patterns CP3 and CP4.

The mold patterns MP may include a first mold pattern MP1 and a second mold pattern MP2. The second mold pattern MP2 may be located at a higher level than that of the first mold pattern MP1. The first mold pattern MP1 may be located at the same level as that of the first conductive pattern CP1 and the third conductive pattern CP3. The second mold pattern MP2 may be located at the same level as that of the second conductive pattern CP2 and the fourth conductive pattern CP4. The first mold pattern MP1 may be in contact with the first conductive pattern CP1 and the third conductive pattern CP3. The second mold pattern MP2 may be in contact with the second conductive pattern CP2 and the fourth conductive pattern CP4.

The dielectric patterns IP may be disposed between the first and second conductive patterns CP1 and CP2. The dielectric patterns IP may be disposed between the third and fourth conductive patterns CP3 and CP4. The dielectric patterns IP may be disposed between the first and second mold patterns MP1 and MP2.

The first and second conductive patterns CP1 and CP2 may be disposed between the first side separation structure SDS1 and the dielectric structure IS. The third and fourth conductive patterns CP3 and CP4 may be disposed between the second side separation structure SDS2 and the dielectric structure IS.

The first and third conductive patterns CP1 and CP3 may be spaced apart from each other in the first direction D1. The second and fourth conductive patterns CP2 and CP4 may be spaced apart from each other in the first direction D1. The central separation structure CDS and the dielectric structure IS may be disposed between the first and third conductive patterns CP1 and CP3 and between the second and fourth conductive patterns CP2 and CP4.

The memory channel structure CH may penetrate in the third direction D3 through the first and second conductive patterns CP1 and CP2, or may penetrate in the third direction D3 through the third and fourth conductive patterns CP3 and CP4.

The first connection contact structure CS1 may include a first connection contact CC1 and a first connection contact dielectric layer CI1. The first connection contact dielectric layer CI1 may surround the first connection contact CC1. The first connection contact CC1 may include a conductive material. The first connection contact dielectric layer CI1 may include a dielectric material.

Each of the first conductive pattern CP1 and the third conductive pattern CP3 may be electrically connected to the first connection contact structure CS1. Each of the first conductive pattern CP1 and the third conductive pattern CP3 may be electrically connected to the first connection contact CC1. The first connection contact structures CS1 may be electrically connected to the first conductive pattern CP1, the third conductive pattern CP3, and the conductive patterns CP located at a lower level than that of the first and third conductive patterns CP1 and CP3. The first connection contacts CC1 may be electrically connected to the first conductive pattern CP1, the third conductive pattern CP3, and the conductive patterns CP located at a lower level than that of the first and third conductive patterns CP1 and CP3.

The first connection contact structure CS1 may be in contact with at least a portion of the mold patterns MP and at least a portion of the conductive patterns CP. The first connection contact dielectric layer CI1 may be in contact with at least a portion of the mold patterns MP and at least a portion of the conductive patterns CP. The first connection contact CC1 may be in contact with the mold pattern MP and the conductive pattern CP.

The first connection contact structure CS1 may be disposed between the mold pattern MP and the conductive pattern CP. For example, the first connection contact structure CS1 electrically connected to the first conductive pattern CP1 may be disposed between the second mold pattern MP2 and the second conductive pattern CP2. The first connection contact dielectric layer CI1 may be disposed between the mold pattern MP and the conductive pattern CP. For example, the first connection contact dielectric layer CI1 of the first connection contact structure CS1 electrically connected to the first conductive pattern CP1 may be disposed between the second mold pattern MP2 and the second conductive pattern CP2. The first connection contact CC1 may be disposed between the mold pattern MP and the conductive pattern CP. For example, the first connection contact CC1 of the first connection contact structure CS1 electrically connected to the first conductive pattern CP1 may be disposed between the second mold pattern MP2 and the second conductive pattern CP2.

The second connection contact structure CS2 may include a second connection contact CC2 and a second connection contact dielectric layer CI2. The second connection contact dielectric layer CI2 may surround the second connection contact CC2. The second connection contact CC2 may include a conductive material. The second connection contact dielectric layer CI2 may include a dielectric material.

Each of the second conductive pattern CP2 and the fourth conductive pattern CP4 may be electrically connected to the second connection contact structure CS2. Each of the second conductive pattern CP2 and the fourth conductive pattern CP4 may be electrically connected to the second connection contact CC2. The second connection contact structures CS2 may be correspondingly connected to the conductive patterns CP located at higher levels than that of the first conductive pattern CP1 and the third conductive pattern CP3. The second connection contacts CC2 may be correspondingly connected to the conductive patterns CP located at higher levels than that of the first conductive pattern CP1 and the third conductive pattern CP3.

When viewed in plan as shown in FIG. 2A, the second connection contact structure CS2 may be surrounded by the conductive pattern CP. When viewed in plan as shown in FIG. 2A, the second connection contact dielectric layer CI2 may be surrounded by the conductive pattern CP. The second connection contact CC2 may be in contact with the conductive pattern CP. When viewed in a plan view as in FIG. 2A, the central separation structure CDS and the dielectric structure IS may have a ribbed profile; example embodiments are not limited thereto.

A length in the third direction D3 of the second connection contact CC2 may be less than a length in the third direction D3 of the first connection contact CC1.

Referring to FIGS. 2E, 2F, and 2G, the conductive pattern CP may have a first sidewall CP_S1 in contact with the central separation structure CDS, a second sidewall CP_S2 in contact with the dielectric structure IS, and a third sidewall CP_S3 in contact with the mold pattern MP.

The dielectric structure IS may have a first sidewall IS_S1 in contact with the second sidewall CP_S2 of the conductive pattern CP and a second sidewall IS_S2 in contact with the mold pattern MP.

The mold pattern MP may have a first sidewall MP_S1 and a second sidewall MP_S2. The first sidewall MP_S1 and the second sidewall MP_S2 of the mold pattern MP may be in contact with the third sidewalls CP_S3 of the conductive patterns CP that are different from each other. The mold pattern MP may have a third sidewall MP_S3 and a fourth sidewall MP_S4. Each of the third and fourth sidewalls MP_S3 and MP_S4 of the mold pattern MP may be in contact with the second sidewall IS_S2 of the dielectric structure IS.

The first connection contact structure CS1 may have a first sidewall CS1_S1 and a second sidewall CS1_S2. The first sidewall CS1_S1 of the first connection contact structure CS1 may be in contact with at least one conductive pattern CP. The second sidewall CS1_S2 of the first connection contact structure CS1 may be in contact with at least one mold pattern MP. The first sidewall CS1_S1 and the second sidewall CS1_S2 of the first connection contact structure CS1 may be a first sidewall and a second sidewall of the first connection contact dielectric layer CI1.

The second conductive pattern CP2 may have a surface CP2_O1 in contact with the first sidewall CS1_S1 of the first connection contact structure CS1 electrically connected to the first conductive pattern CP1. The second mold pattern MP2 may have a surface MP2_O1 in contact with the second sidewall CS1_S2 of the first connection contact structure CS1 electrically connected to the first conductive pattern CP1.

A bottom surface CS1_L of the first connection contact structure CS1 may include a bottom surface CC1_L of the first connection contact CC1 and a bottom surface CI1_L of the first connection contact dielectric layer CI1. The bottom surface CS1_L of the first connection contact structure CS1 may be in contact with the conductive pattern CP and the mold pattern MP.

The first conductive pattern CP1 may have a first surface CP1_O1 in contact with the first sidewall CS1_S1 of the first connection contact structure CS1 electrically connected to the first conductive pattern CP1. The first conductive pattern CP1 may have a second surface CP1_O2 in contact with the bottom surface CS1_L of the first connection contact structure CS1 electrically connected to the first conductive pattern CP1.

The first mold pattern MP1 may have a first surface MP1_O1 in contact with the second sidewall CS1_S2 of the first connection contact structure CS1 electrically connected to the first conductive pattern CP1. The first mold pattern MP1 may have a second surface MP1_O2 in contact with the bottom surface CS1_L of the first connection contact structure CS1 electrically connected to the first conductive pattern CP1.

The first surface MP1_O1 of the first mold pattern MP1 may be in contact with the second sidewall CS1_S2 of the first connection contact dielectric layer CI1 of the first connection contact structure CS1 electrically connected to the first conductive pattern CP1.

The second surface MP1_O2 of the first mold pattern MP1 may be in contact with the bottom surface CC1_L of the first connection contact CC1 of the first connection contact structure CS1 electrically connected to the first conductive pattern CP1 and with the bottom surface CI1_L of the first connection contact dielectric layer CI1.

The first surface CP1_O1 of the first conductive pattern CP1 may be in contact with the first sidewall CS1_S1 of the first connection contact dielectric layer CI1 of the first connection contact structure CS1 electrically connected to the first conductive pattern CP1.

The second surface CP1_O2 of the first conductive pattern CP1 may be in contact with the bottom surface CC1_L of the first connection contact CC1 of the first connection contact structure CS1 electrically connected to the first conductive pattern CP1 and with the bottom surface CI1_L of the first connection contact dielectric layer CI1.

The first surface MP1_ O1 of the first mold pattern MP1 may connect the second surface MP1_O2 of the first mold pattern MP1 to a top surface of the first mold pattern MP1. The first surface CP1_O1 of the first conductive pattern CP1 may connect the second surface CP1_O2 of the first conductive pattern CP1 to the top surface of the first conductive pattern CP1. The second surface MP1_O2 of the first mold pattern MP1 may be coplanar with the second surface CP1_O2 of the first conductive pattern CP1.

The third conductive pattern CP3 may include a first overlap part CP3_OV that overlaps in the third direction D3 with the first connection contact CC1 of the first connection contact structure CS1 electrically connected to the third conductive pattern CP3. The first mold pattern MP1 may include a second overlap part MP1_OV that overlaps in the third direction D3 with the first connection contact CC1 of the first connection contact structure CS1 electrically connected to the third conductive pattern CP3. The first overlap part CP3_OV and the second overlap part MP1_OV may be in contact with each other.

The first conductive pattern CP1 may include an overlap part that overlaps or at least partly overlaps in the third direction D3 with the first connection contact CC1 of the first connection structure CS1 electrically connected to the first conductive pattern CP1.

The mold pattern MP may include a first part 22, a second part 23, and a third part 21. Each of the first part 22 and the second part 23 may be disposed between the dielectric structure IS and the conductive pattern CP. For example, the first part 22 of the second mold pattern MP2 may be disposed between the second conductive pattern CP2 and the dielectric structure IS, and the second part 23 of the second mold pattern MP2 may be disposed between the fourth conductive pattern CP4 and the dielectric structure IS. The third part 21 may connect the first part 22 and the second part 23 to each other. The dielectric structure IS may be disposed between the first part 22 and the second part 23.

In some example embodiments, the first connection contact CC1 of the first connection contact structure CS1 electrically connected to the first conductive pattern CP1 may be in contact with the first part 22 of the first mold pattern MP1.

The first part 22 of the second mold pattern MP2 may have a sidewall in contact with the second conductive pattern CP2. The second part 23 of the second mold pattern MP2 may have a sidewall in contact with the fourth conductive pattern CP4. A distance L1 in the first direction D1 between the sidewalls of the first and second parts 22 and 23 of the second mold pattern MP2 may decrease with decreasing distance from the memory channel structure CH or the central separation structure CDS.

The central separation structure CDS may include a base part 11 and protrusion parts 12. The base part 11 may extend in the third direction D3. The protrusion parts 12 may protrude in the first direction D1 or in an opposite direction from the base part 11.

The protrusion part 12 may have a sidewall 12_S in contact with the first sidewall CP_S1 of the conductive pattern CP, a top surface 12_U in contact with a bottom surface of the dielectric pattern IP, and a bottom surface 12_L in contact with a top surface of the dielectric pattern IP. The base part 11 may have a sidewall 11_S in contact with a sidewall IP_S of the dielectric pattern IP. The sidewall 11_S of the base part 11 may be disposed between the protrusion parts 12 that are adjacent to each other in the third direction D3. The sidewall 11_S of the base part 11 may connect to each other the top and bottom surfaces 12_U and 12_L of the protrusion parts 12 that are adjacent to each other in the third direction D3.

Similar to the central separation structure CDS, each of the first and second side separation structures SDS1 and SDS2 may include a base part and protrusion parts.

The first and second sidewalls IS_S1 and IS_S2 of the dielectric structure IS may be flat. A length in the third direction D3 of the first sidewall IS_S1 and the second sidewall IS_S2 of the dielectric structure IS may be greater than a length in the third direction D3 of the sidewall 11_S of the base part 11 and a length in the third direction D3 of the sidewall 12_S of each of the protrusion parts 12.

A maximum width W1 in the first direction D1 of the central separation structure CDS may be greater than a maximum width W2 in the first direction D1 of the dielectric structure IS. The maximum width W1 in the first direction D1 of the central separation structure CDS may be or may correspond to a width in the first direction D1 between the sidewalls 12_S of the protrusion parts 12. A maximum width in the first direction D1 of each of the first and second side separation structures SDS1 and SDS2 may be greater than the maximum width W2 in the first direction D1 of the dielectric structure IS.

The dielectric structure IS may include a first dielectric part 31 in contact with the mold pattern MP, a second dielectric part 32 in contact with the conductive patterns CP, and a third dielectric part 33 in contact with the central separation structure CDS. The dielectric structure IS may have a third sidewall IS3 in contact with the central separation structure CDS. A maximum width in the first direction D1 of the third dielectric part 33 may be less than a maximum width in the first direction D1 of the first dielectric part 31 and the maximum width W2 in the first direction D1 of the second dielectric part 32.

In a semiconductor device according to some example embodiments, the mold patterns MP may support (e.g., may physically support) the dielectric patterns IP. Therefore, the dielectric patterns IP may be stably supported, and the semiconductor device may improve in stability.

As the dielectric patterns IP may be more stably supported, there may be a reduction in the number of the dummy structures DH. The reduction in the number of the dummy structures DH may prevent or reduce interference between the dummy structure DH and the first connection contact structure CS1, and the first connection contact structures CS1 may be formed sufficiently large to have relatively large lengths.

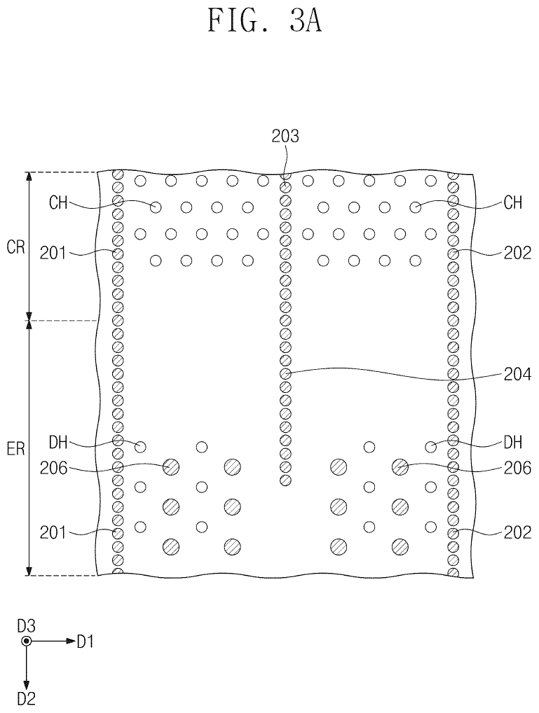

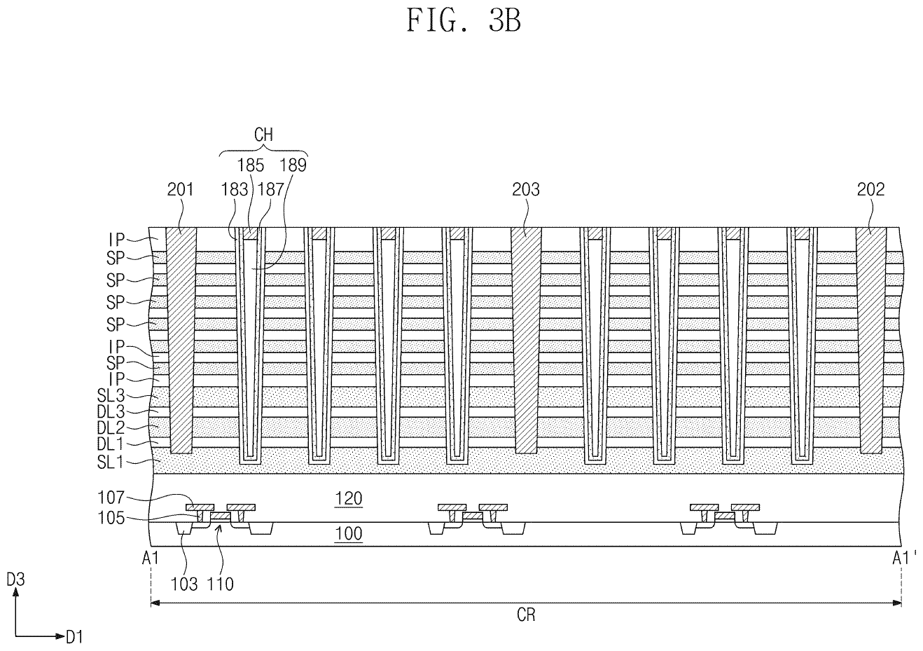

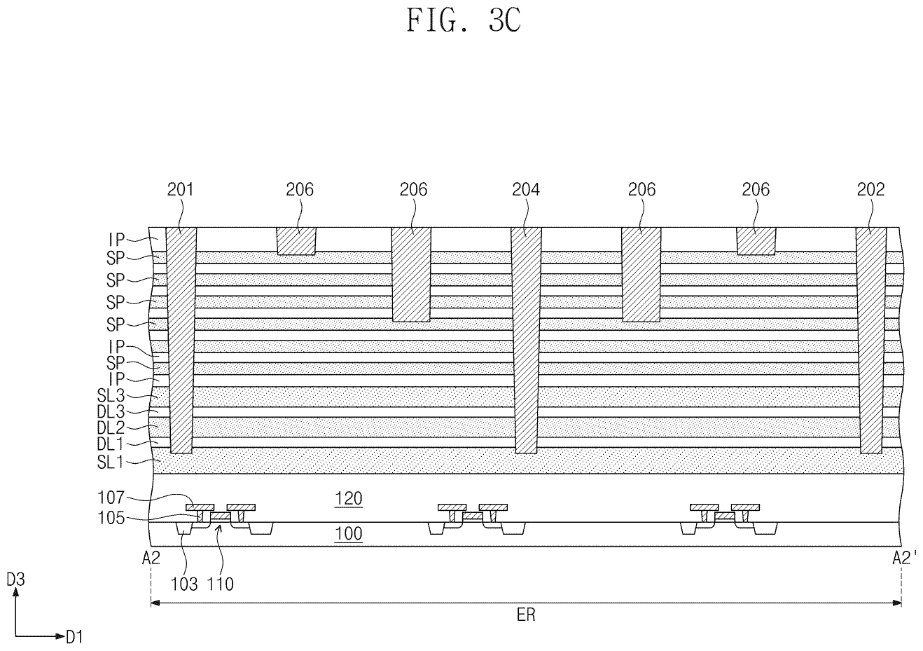

FIGS. 3A, 3B, 3C, 4A, 4B, 5A, 5B, 6A, 6B, 6C, 7A, 7B, 7C, 8A, and 8B illustrate diagrams showing a method of fabricating a semiconductor device depicted in FIGS. 2A to 2G.

Referring to FIGS. 3A, 3B, and 3C, device isolation layers 103 and transistors 110 may be formed on a substrate 100. A peripheral circuit dielectric layer 120 may be formed on the substrate 100. Peripheral contacts 105 and peripheral conductive lines 107 may be formed in the peripheral circuit dielectric layer 120.

A first source layer SL1, a first dummy layer DL1, a second dummy layer DL2, a third dummy layer DL3, and a third source layer SL3 may be sequentially formed on the peripheral circuit dielectric layer 120.

Dielectric patterns IP and sacrificial patterns SP may be alternately formed on the third source layer SL3. The sacrificial patterns SP may include a dielectric material having an etch selectivity with respect to a material included in the dielectric patterns IP. For example, the sacrificial patterns SP may include nitride, and the dielectric patterns IP may include oxide.

There may be formed memory channel structures CH, dummy structures DH, first sacrificial pillars 201, second sacrificial pillars 202, third sacrificial pillars 203, and fourth sacrificial pillars 204.

The formation of the memory channel structures CH, the dummy structures DH, the first sacrificial pillars 201, the second sacrificial pillars 202, the third sacrificial pillars 203, and the fourth sacrificial pillars 204 may include forming channel holes, dummy holes, first holes, second holes, third holes, and fourth holes, forming the first sacrificial pillars 201 in the first holes, forming the second sacrificial pillars 202 in the second holes, forming the third sacrificial pillars 203 in the third holes, forming the fourth sacrificial pillars 204 in the fourth holes, forming the dummy structures DH in the dummy holes, and forming the memory channel structures CH in the channel holes. In some example embodiments, the forming the holes may be based on or may include an etching process such as but not limited to a wet etching process and/or a dry etching process. In some example embodiments, the forming the pillars may be based on or may include a filling process, for example, a deposition process such as one or more of a chemical vapor deposition (CVD) process or a physical vapor deposition (PVD) process; example embodiments are not limited thereto. The first, second, third, and fourth sacrificial pillars 201, 202, 203, and 204 may have an etch selectivity with respect to the dielectric pattern IP and the sacrificial pattern SP. For example, the first, second, third, and fourth sacrificial pillars 201, 202, 203, and 204 may include metal or silicon.

In some example embodiments, the channel holes, the dummy holes, the first holes, the second holes, the third holes, and the fourth holes may be formed simultaneously with each other. In some example embodiments, the formation of the memory channel structures CH in the channel holes may include forming channel sacrificial pillars in the channel holes, removing the channel sacrificial pillars to open the channel holes, and forming the memory channel structures CH in the opened channel holes. In this case, the channel sacrificial pillars may be formed simultaneously with the first, second, third, and fourth sacrificial pillars 201, 202, 203, and 204. In some example embodiments, the formation of the dummy structures DH may include forming dummy sacrificial pillars in the dummy holes, removing the dummy sacrificial pillars to open the dummy holes, and forming the dummy structures DH in the opened dummy holes. In this case, the dummy sacrificial pillars may be formed simultaneously with the first, second, third, and fourth sacrificial pillars 201, 202, 203, and 204.

The memory channel structures CH, the dummy structures DH, the first sacrificial pillars 201, the second sacrificial pillars 202, the third sacrificial pillars 203, and the fourth sacrificial pillars 204 may penetrate in the third direction D3 through the dielectric patterns IP and the sacrificial patterns SP.

Contact sacrificial pillars 206 may be formed. The formation of the contact sacrificial pillars 206 may include forming contact holes and forming the contact sacrificial pillars 206 in the contact holes.

Each of the contact sacrificial pillars 206 may be in contact with at least one sacrificial pattern SP.

The first sacrificial pillars 201 may be arranged spaced apart from each other in the second direction D2. The second sacrificial pillars 202 may be arranged spaced apart from each other in the second direction D2. The third sacrificial pillars 203 may be arranged spaced apart from each other in the second direction D2. The fourth sacrificial pillars 204 may be arranged spaced apart from each other in the second direction D2. The third and fourth sacrificial pillars 203 and 204 may be arranged in the second direction D2.

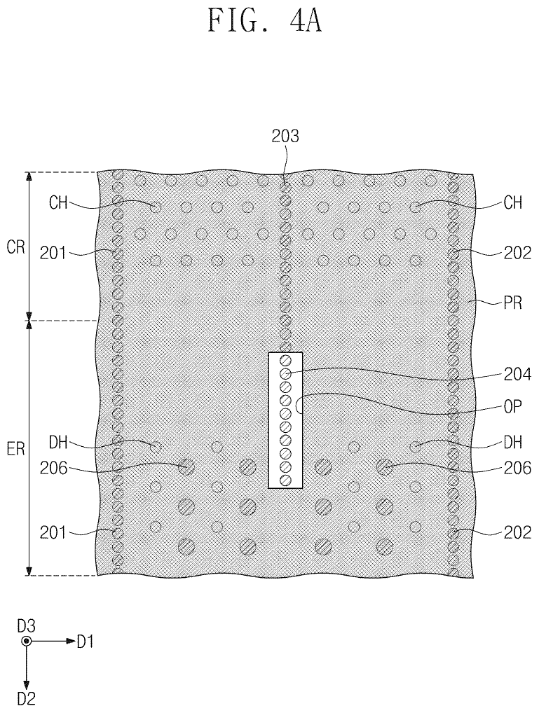

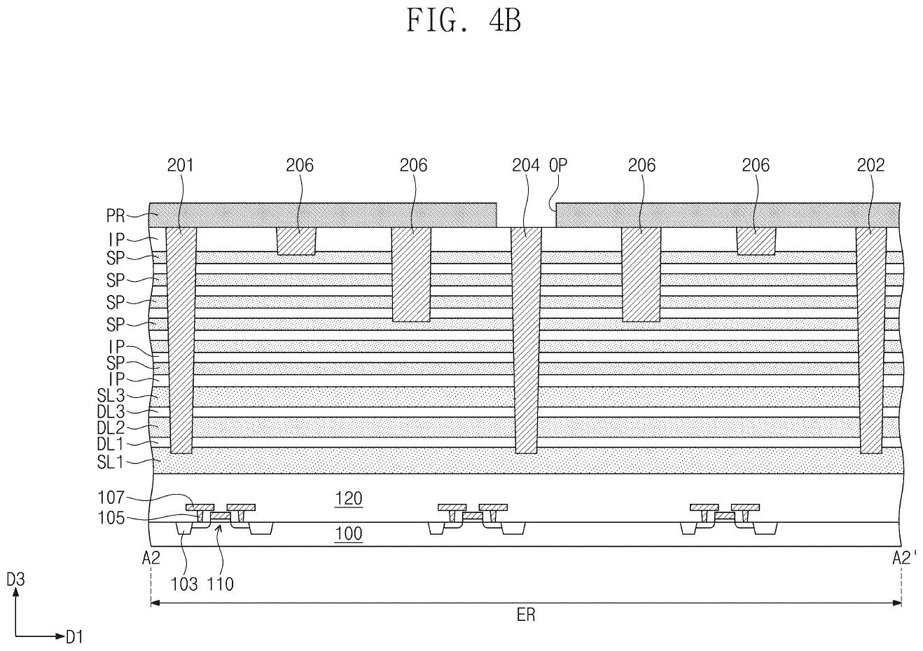

Referring to FIGS. 4A and 4B, a photoresist layer PR may be formed to cover the first, second, and third sacrificial pillars 201, 202, and 203, the memory channel structures CH, the dummy structures DH, and the contact sacrificial pillars 206. The photoresist layer PR may include an opening OP that exposes the fourth sacrificial pillars 204. The opening OP may be formed by exposing and developing the photoresist layer PR. The opening OP may be formed with a photolithographic process. The photoresist layer PR may include a photoresist material.

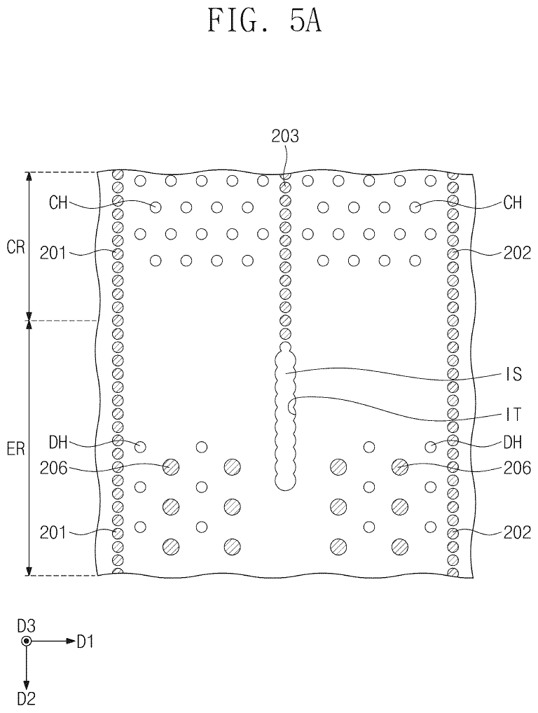

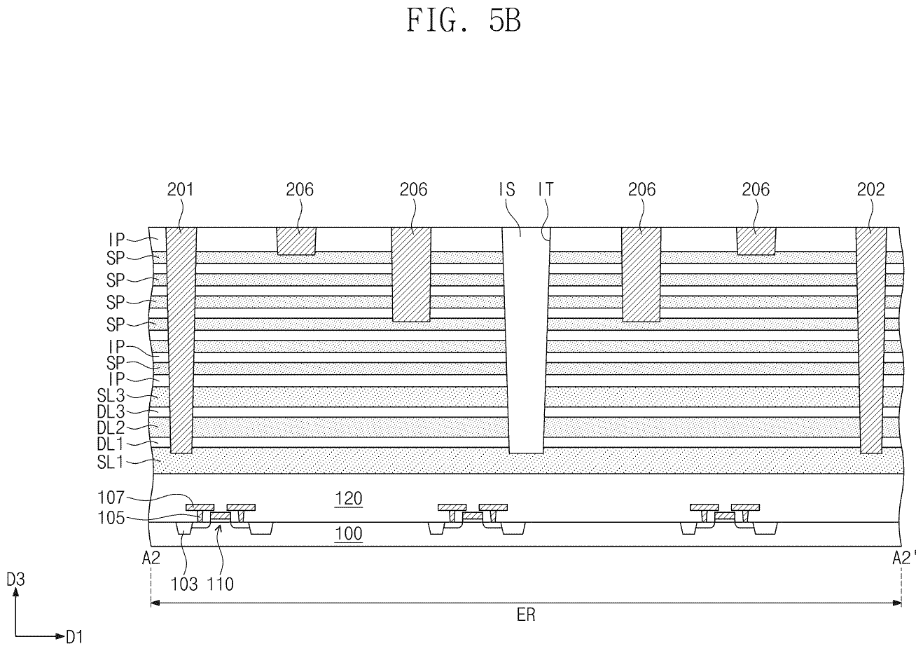

Referring to FIGS. 5A and 5B, the fourth sacrificial pillars 204 may be removed through the openings OP of the photoresist layer PR. The fourth sacrificial pillars 204 may be removed to open the fourth holes.

A process may be performed to expand the fourth holes. The expansion of the fourth holes may connect the fourth holes to each other and to form a dielectric trench IT. The expansion of the fourth holes may be based on an isotropic etching process such as a wet etching process; however, example embodiments are not limited thereto.

In some example embodiments, in removing the fourth sacrificial pillars 204 and expanding the fourth holes, the third sacrificial pillar 203 disposed closest to the fourth sacrificial pillars 204 may be removed. The third hole opened due to the removal of the third sacrificial pillar 203 may be connected to the expanded fourth hole, thereby being defined as a portion of the dielectric trench IT.

A dielectric structure IS may be formed in the dielectric trench IT. The dielectric structure IS may penetrate in the third direction D3 through the dielectric patterns IP and the sacrificial patterns SP.

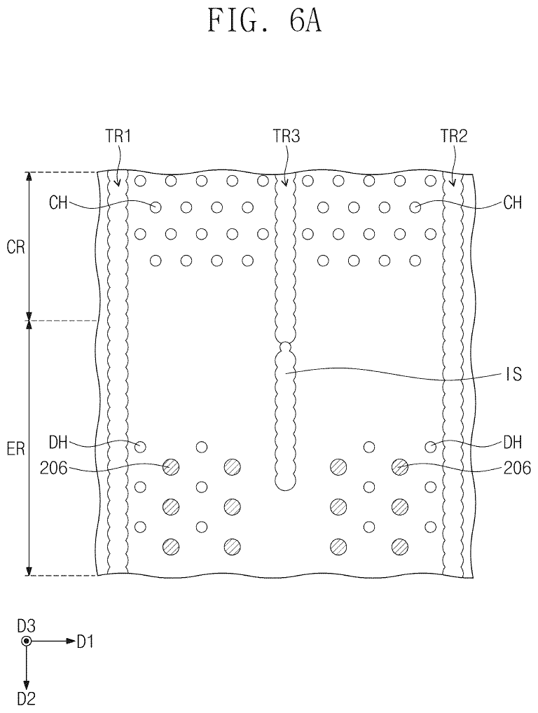

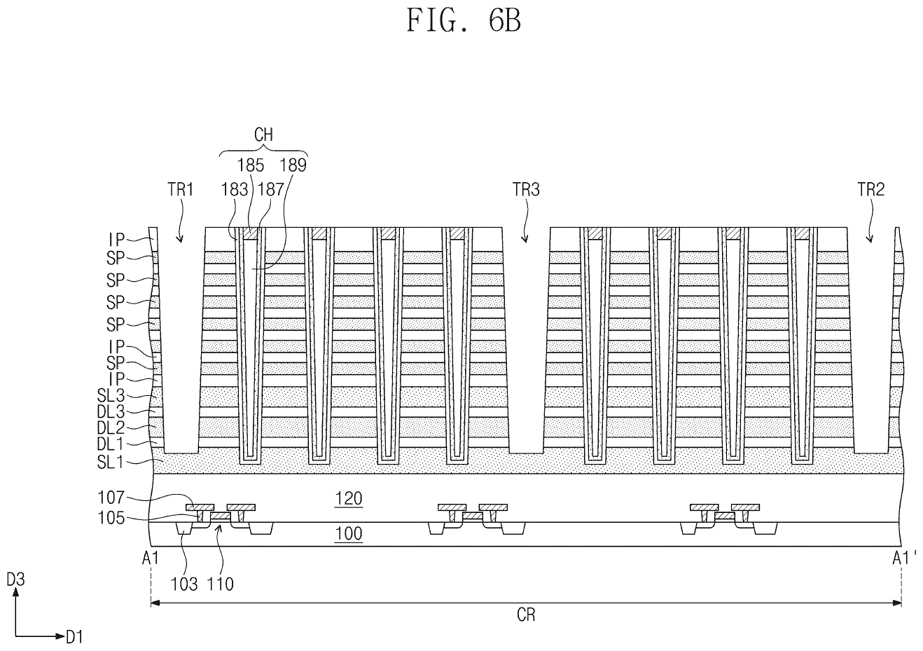

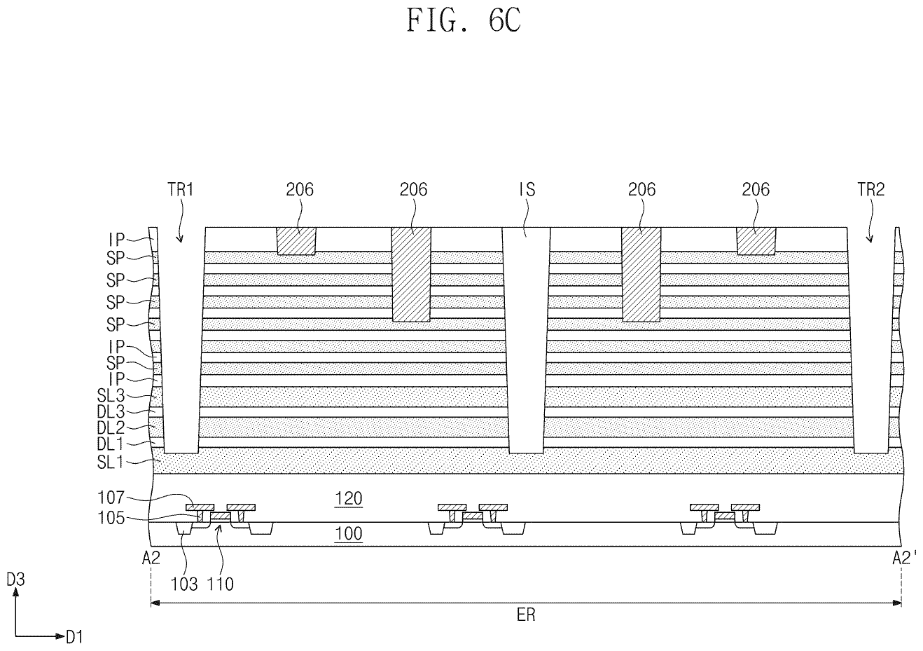

Referring to FIGS. 6A and 6B, the first, second, and third sacrificial pillars 201, 202, and 203 may be removed. The removal of the first, second, and third sacrificial pillars 201, 202, and 203 may open the first, second, and third holes.

An expansion process may be performed on the first, second, and third holes. The first holes may be expanded and connected with each other to form a first trench TR1. The expansion process may be based on an isotropic etching process such as a wet etching process; however, example embodiments are not limited thereto. The second holes may be expanded and connected with each other to form a second trench TR2. The third holes may be expanded and connected with each other to form a third trench TR3. The third trench TR3 may be connected to the dielectric structure IS. The first, second, and third trenches TR1, TR2, and TR3 may penetrate in the third direction D3 through the dielectric patterns IP and the sacrificial patterns SP. The third trench TR3 and the dielectric structure IS may be disposed between the first trench TR1 and the second trench TR2.

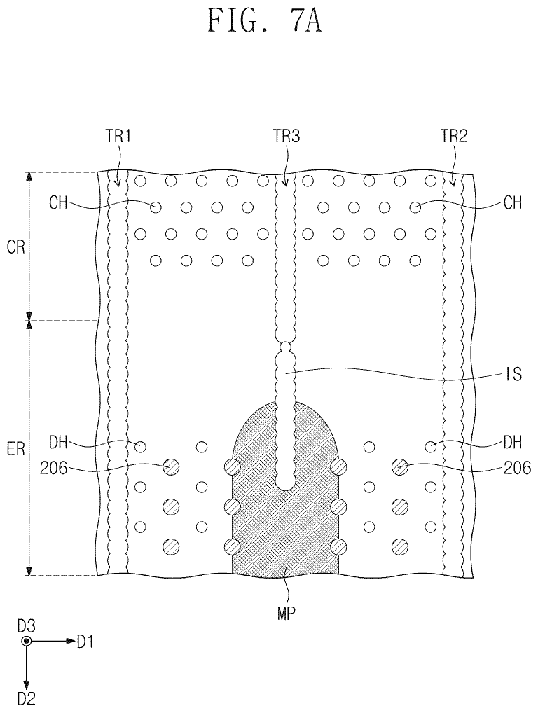

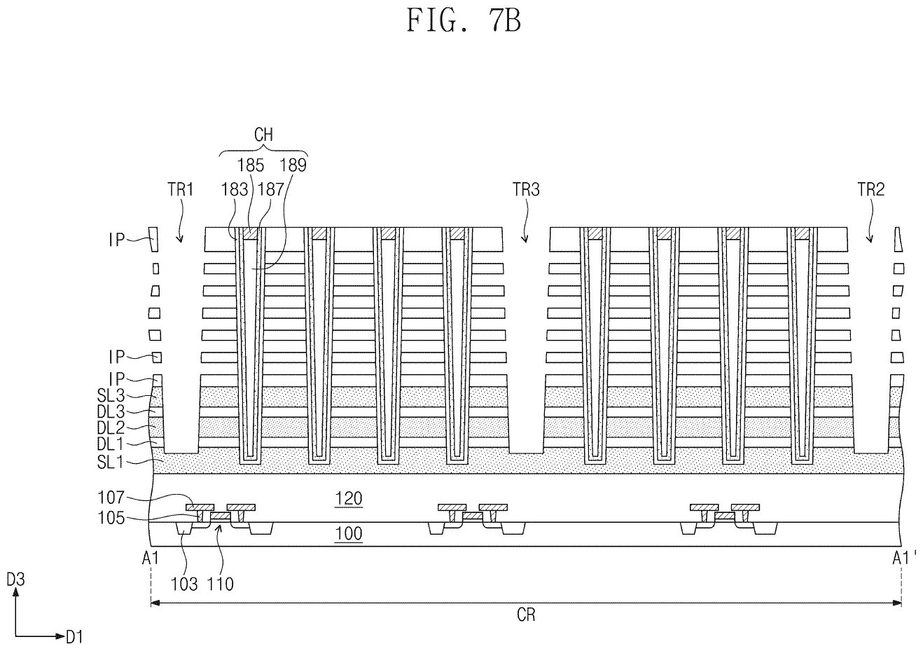

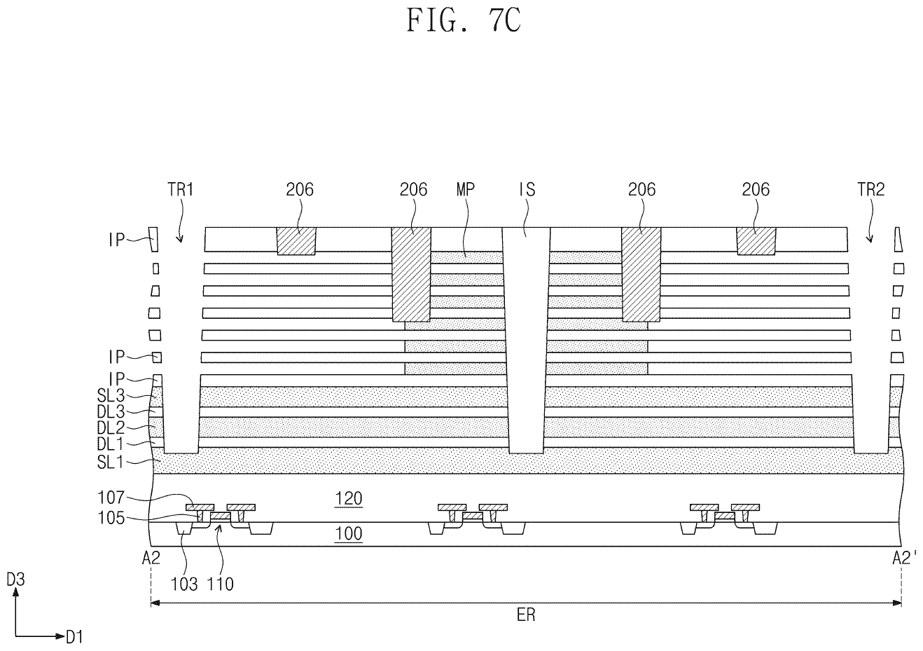

Referring to FIGS. 7A and 7B, the sacrificial patterns SP may be selectively etched through the first trench TR1, the second trench TR2, and the third trench TR3. For example, a phosphoric acid may be provided through the first trench TR1, the second trench TR2, and the third trench TR3.

The sacrificial patterns SP may be etched to form mold patterns MP. Non-etched residues of the sacrificial patterns SP may be defined as the mold patterns MP. The sacrificial patterns SP may include portions in contact with the dielectric structure IS, and the portions of the sacrificial patterns SP may remain in the etching process.

At least a portion of the contact sacrificial pillars 206 may be in contact with the mold pattern MP.

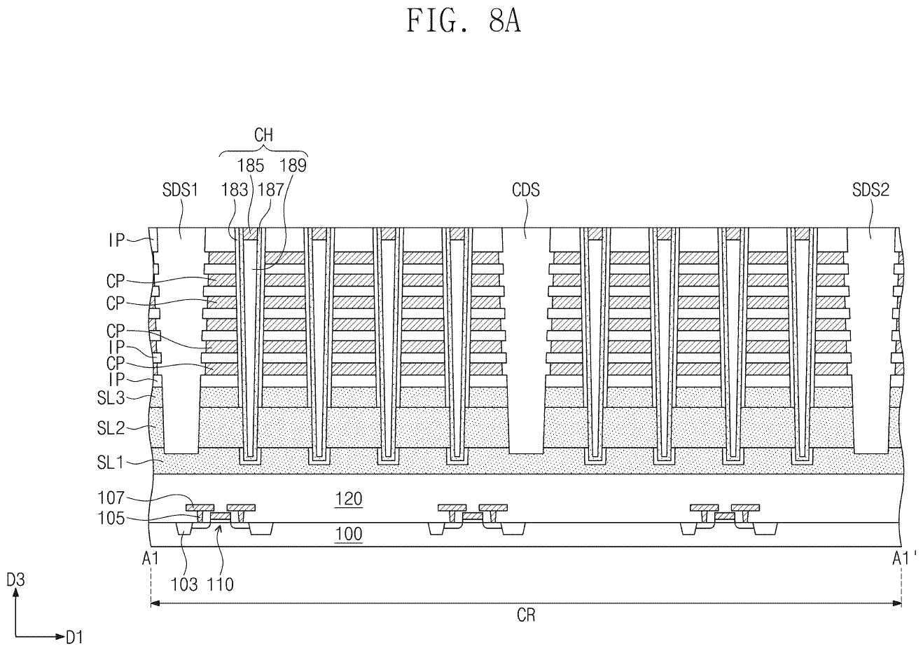

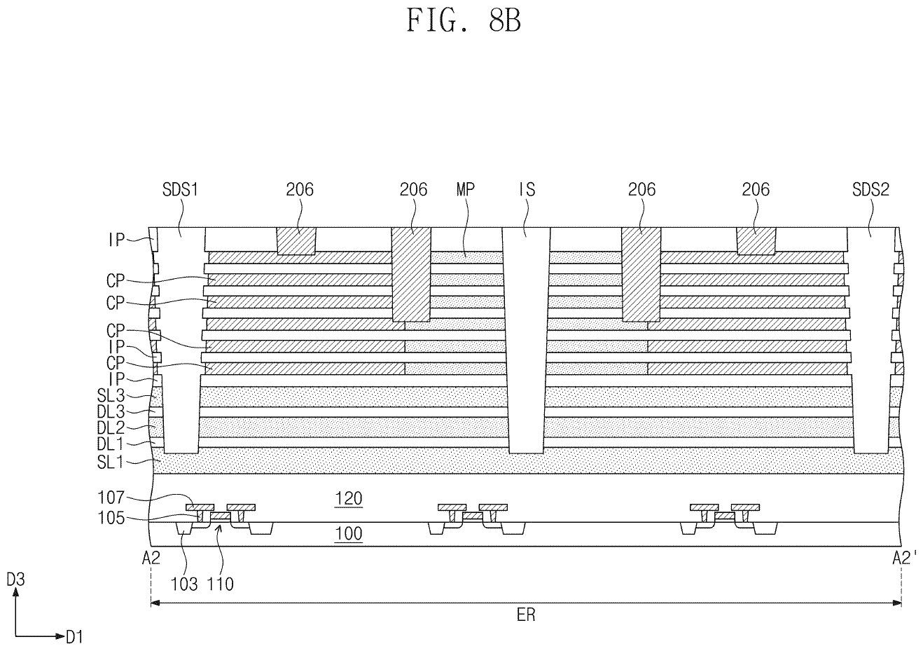

Referring to FIGS. 8A and 8B, conductive patterns CP may be formed. The formation of the conductive patterns CP may include depositing a conductive material through the first trench TR1, the second trench TR2, and the third trench TR3. In some example embodiments, the deposition of conductive material may form conductive connectors, which connect the conductive patterns CP, in the first trench TR1, the second trench TR2, and the third trench TR3. A process may be performed to remove the conductive connectors through the first trench TR1, the second trench TR2, and the third trench TR3. The removal of the conductive connectors may remove portions of the conductive patterns CP adjacent to the first trench TR1, the second trench TR2, and the third trench TR3.

On a cell region CR, the first dummy layer DL1, the second dummy layer DL2, and the third dummy layer DL3 may be removed. A memory layer 183 may be partially removed which is exposed due to the removal of the first dummy layer DL1, the second dummy layer DL2, and the third dummy layer DL3. A second source layer SL2 may be formed.

There may be formed a first side separation structure SDS1, a second side separation structure SDS2, and a central separation structure CDS. The first side separation structure SDS1 may fill the first trench TR1. The second side separation structure SDS2 may fill the second trench TR2. The central separation structure CDS may fill the third trench TR3. The portions of the conductive patterns CP adjacent to the first trench TR1, the second trench TR2, and the third trench TR3 may be removed to form empty spaces, and protrusion parts (see 12 of FIG. 2F) of the central separation structure CDS may be formed in the empty spaces.

Referring back to FIGS. 2A, 2B, 2C, and 2D, the contact sacrificial pillars 206 may be removed. First and second contact connection structures CS1 and CS2 may be formed in empty spaces obtained by removing the contact sacrificial pillars 206.

A first cover dielectric layer 131 may be formed. Bit-line contacts BC and conductive line contacts SC may be formed.

A second cover dielectric layer 132 may be formed. Bit lines BL and conductive lines CL may be formed.

In a method of fabricating a semiconductor device according to some example embodiments, after the sacrificial patterns SP are etched, the mold patterns MP may support the dielectric patterns IP. Accordingly, improved stability may be achieved in the fabrication of the semiconductor device.

Alternatively or additionally in a method of fabricating a semiconductor device according to some example embodiments, the mold patterns MP may support the dielectric patterns IP to reduce the number of the dummy structures DH. Therefore, sizes of the contact sacrificial pillars 206 may be relatively increased without interference with the dummy structures DH.

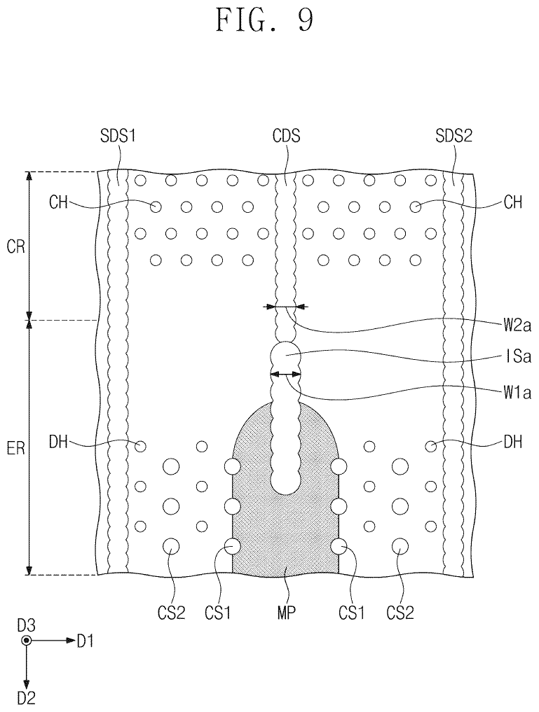

FIG. 9 illustrates a plan view showing a semiconductor device according to some example embodiments. Except the following description, a semiconductor device according to FIG. 9 may be similar to the semiconductor device according to FIGS. 2A to 2G.

Referring to FIG. 9, a maximum width W1a in the first direction D1 of a dielectric structure Isa may be greater than a maximum width W2a in the first direction D1 of the central separation structure CDS.

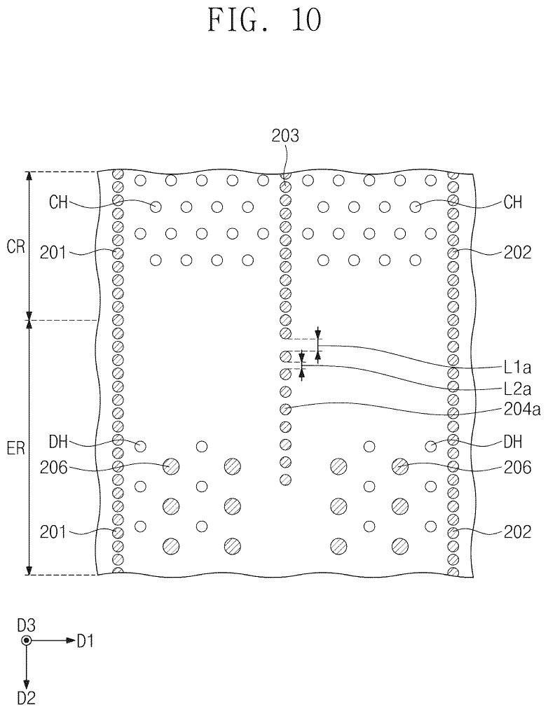

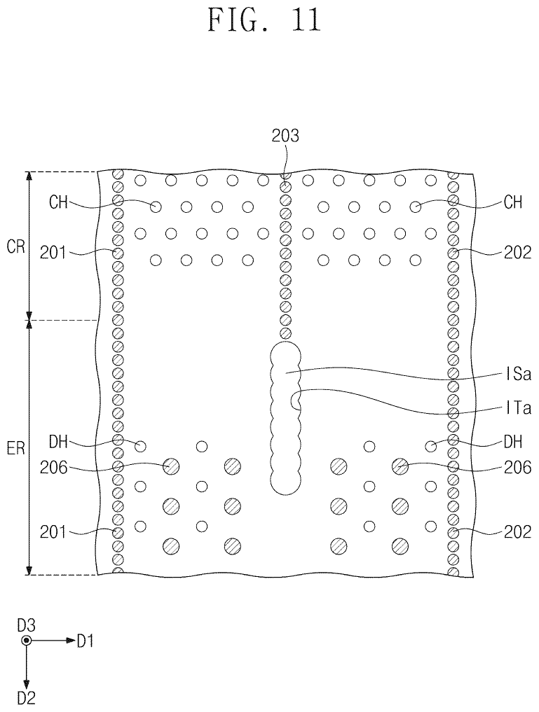

FIGS. 10 and 11 illustrate diagrams showing a method of fabricating a semiconductor device depicted in FIG. 9. Except the following description, a method of fabricating a semiconductor device according to FIGS. 10 and 11 will be similar to the method of fabricating a semiconductor device, which is depicted in FIGS. 2A to 2G, according to FIGS. 3A, 3B, 3C, 4A, 4B, 5A, 5B, 6A, 6B, 6C, 7A, 7B, 7C, 8A, and 8B.

Referring to FIG. 10, there may be formed first sacrificial pillars 201, second sacrificial pillars 202, third sacrificial pillars 203, and fourth sacrificial pillars 204a.

An interval L2a in the second direction D2 between neighboring fourth sacrificial pillars 204a may be greater than an interval in the second direction D2 between neighboring first sacrificial pillars 201, an interval in the second direction D2 between neighboring second sacrificial pillars 202, and an interval in the second direction D2 between neighboring third sacrificial pillars 203.

The interval L2a in the second direction D2 between neighboring fourth sacrificial pillars 204a may be greater than an interval L1a in the second direction D2 between the third sacrificial pillar 203 and the fourth sacrificial pillar 204a.

Referring to FIG. 11, the fourth sacrificial pillars 204a may be removed. An expansion process may be performed on the fourth holes that are opened due to the removal of the fourth sacrificial pillars 204a. The degree of expansion of the fourth holes may be greater than the degree of expansion of the first to third holes in the expansion process (see FIGS. 6A, 6B, and 6C) of the first to third holes. Thus, a maximum width in the first direction D1 of a dielectric trench ITa may be greater than maximum widths in the first direction D1 of the first, second, and third trenches (see TR1, TR2, and TR3 of FIGS. 6A, 6B, and 6C).

A dielectric structure Isa may be formed in the dielectric trench ITa.

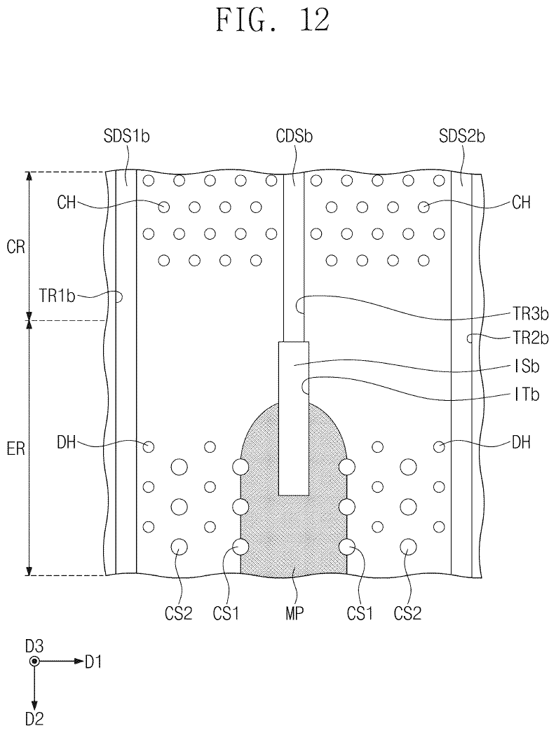

FIG. 12 illustrates a plan view showing a semiconductor device according to some example embodiments. Except the following description, a semiconductor device according to FIG. 12 may be similar to the semiconductor device according to FIGS. 2A to 2G.

Referring to FIG. 12, a first side separation structure SDS1b, a second side separation structure SDS2b, a central separation structure CDSb, and a dielectric structure ISb may include their sidewalls that extend in the second direction D2. The first side separation structure SDS1b, the second side separation structure SDS2b, the central separation structure CDSb, and the dielectric structure ISb may have their flat sidewalls that extend in the second direction D2.

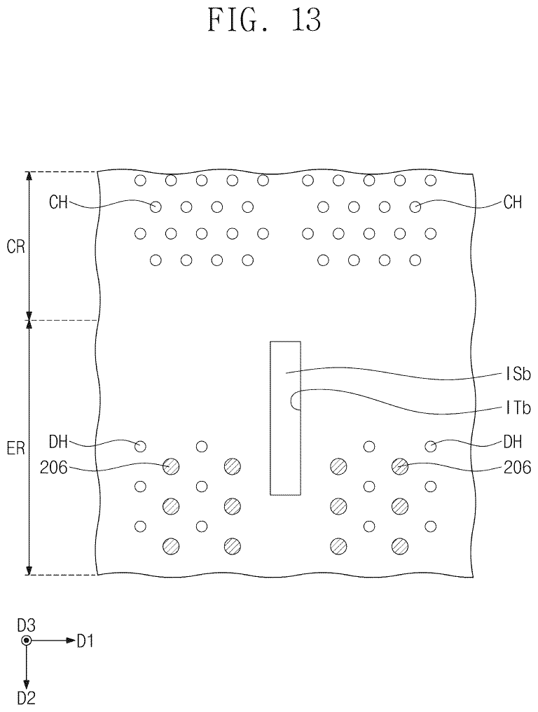

FIG. 13 illustrates a plan view showing a method of fabricating a semiconductor device depicted in FIG. 12. Except the following description, a method of fabricating a semiconductor device according to FIG. 13 will be similar to the method of fabricating a semiconductor device, which is depicted in FIGS. 2A to 2G, according to FIGS. 3A, 3B, 3C, 4A, 4B, 5A, 5B, 6A, 6B, 6C, 7A, 7B, 7C, 8A, and 8B.

Referring to FIG. 13, a dielectric trench ITb may be formed which includes sidewalls that extend in the second direction D2. A dielectric structure ISb may be formed in the dielectric trench ITb.

Referring back to FIG. 12, a first trench TR1b, a second trench TR2b, and a third trench TR3b may be formed each of which includes sidewalls that extend in the second direction D2. The sacrificial patterns SP may be etched (see FIGS. 7A, 7B, and 7C), and a first side separation structure SDS1b, a second side separation structure SDS2b, and a central separation structure CDSb may be formed.

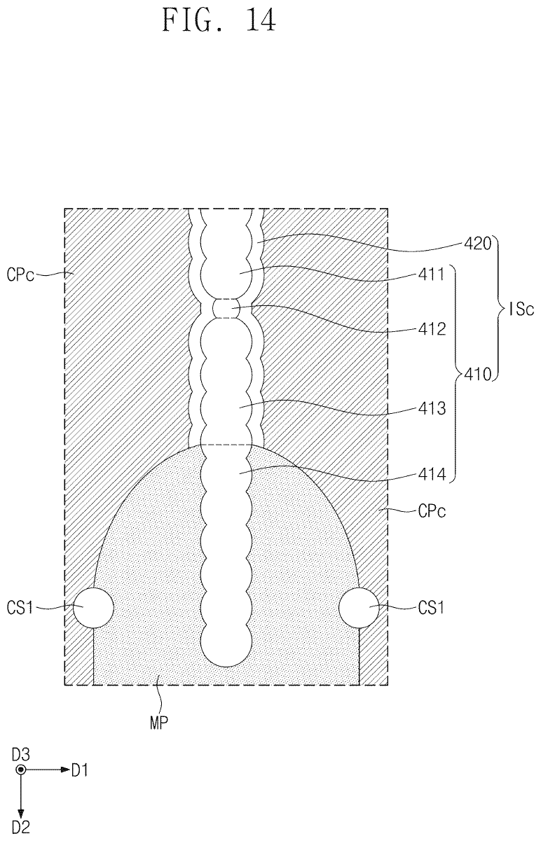

FIG. 14 illustrates an enlarged plan view showing a semiconductor device according to some example embodiments. Except the following description, a semiconductor device according to FIG. 12 may be similar to the semiconductor device according to FIGS. 2A to 2G.

Referring to FIG. 14, a dielectric structure ISc may include a base part 410 and protrusion parts 420 that protrude from the base part 410. The base part 410 may include a first dielectric part 411, a second dielectric part 412, a third dielectric part 413, and a fourth dielectric part 414. The first, second, and third dielectric parts 411, 412, and 413 may be disposed between conductive patterns CPc. The first, second, and third dielectric parts 411, 412, and 413 may be spaced apart from the mold pattern MP. The protrusion parts 420 may protrude from the first, second, and third dielectric parts 411, 412, and 413.

The fourth dielectric part 414 may be in contact with the mold pattern MP. The protrusion part 420 may be in contact with the conductive pattern CPc. The protrusion part 420 may be in contact with the mold pattern MP.

The second dielectric part 412 may be disposed between the first dielectric part 411 and the third dielectric part 413. A maximum width in the first direction D1 of the second dielectric part 412 may be less than a maximum width in the first direction D1 of the first dielectric part 411 and a maximum width in the first direction D1 of the third dielectric part 413.

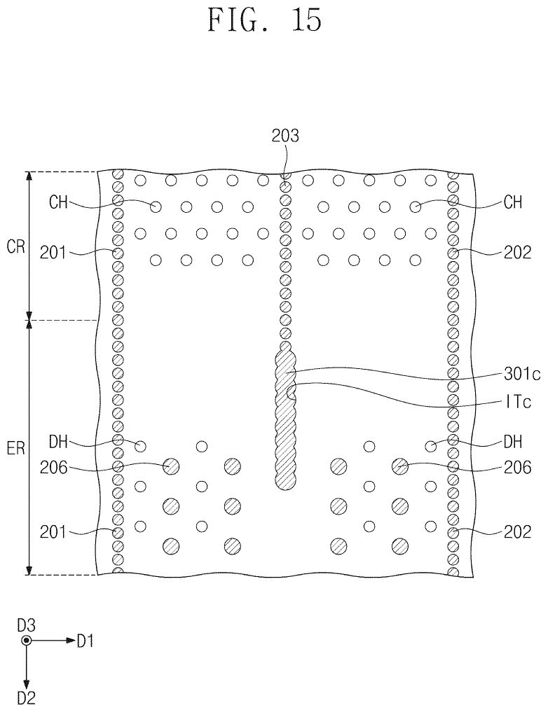

FIGS. 15, 16, and 17 illustrate plan views showing a method of fabricating a semiconductor device depicted in FIG. 14. Except the following description, a method of fabricating a semiconductor device according to FIGS. 15, 16, and 17 will be similar to the method of fabricating a semiconductor device, which is depicted in FIGS. 2A to 2G, according to FIGS. 3A, 3B, 3C, 4A, 4B, 5A, 5B, 6A, 6B, 6C, 7A, 7B, 7C, 8A, and 8B.

Referring to FIG. 15, there may be formed first sacrificial pillars 201, second sacrificial pillars 202, third sacrificial pillars 203, and a sacrificial structure 301c. The formation of the sacrificial structure 301c may include forming the first sacrificial pillars 201, the second sacrificial pillars 202, the third sacrificial pillars 203, and the fourth sacrificial pillars (see 204 of FIG. 3A), removing the fourth sacrificial pillars 204, forming a dielectric trench ITc by expanding the fourth holes from which the fourth sacrificial pillars 204 are removed, and forming the sacrificial structure 301c in the dielectric trench ITc.

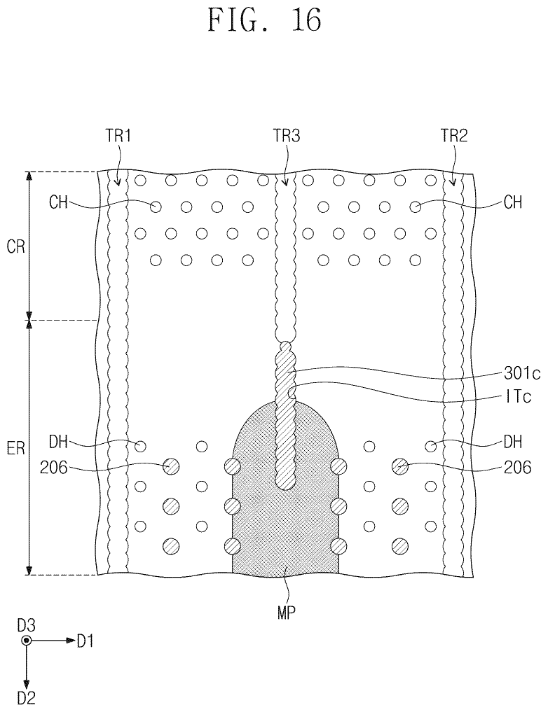

Referring to FIG. 16, the first, second, and third sacrificial pillars 201, 202, and 203 may be removed. The first, second, and third holes may be expanded to form a first trench TR1, a second trench TR2, and a third trench TR3. The third trench TR3 may be connected to the sacrificial structure 301c. Mold patterns MP may be formed.

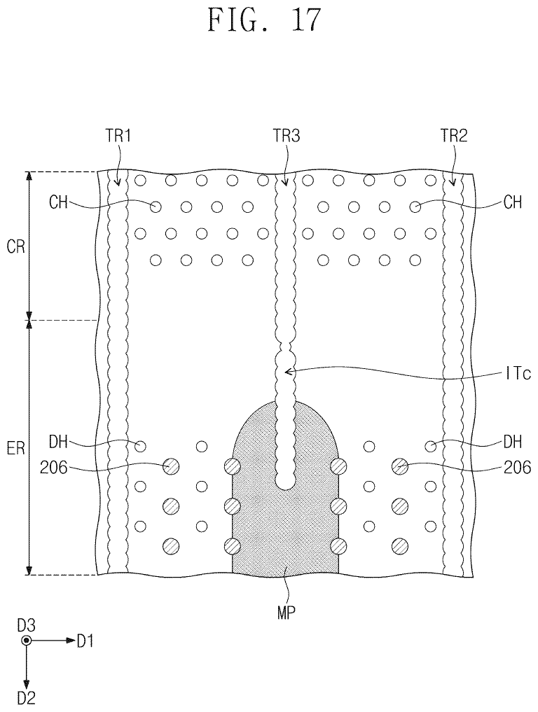

Referring to FIG. 17, the sacrificial structure 301c may be removed. The removal of the sacrificial structure 301c may open the dielectric trench ITc.

Referring back to FIG. 14, conductive patterns CPc may be formed through the third trench TR3 and the dielectric trench ITc. Similar to that discussed in FIGS. 8A and 8B, a process may be performed to remove conductive connectors, and a removal action may be performed on portions of the conductive patterns CPc adjacent to the third trench TR3 and the dielectric trench ITc.

A dielectric structure ISc may be formed to fill the third trench TR3 and the dielectric trench ITc. The protrusion parts 420 of the dielectric structure ISc may fill empty spaces obtained by removing the portions of the conductive patterns CPc adjacent to the third trench TR3 and the dielectric trench ITc.

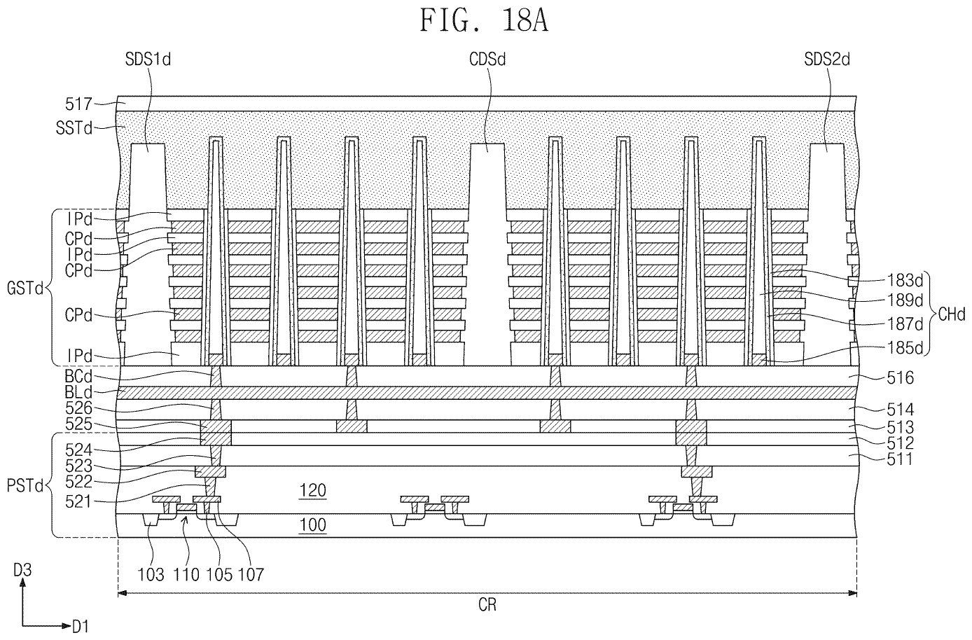

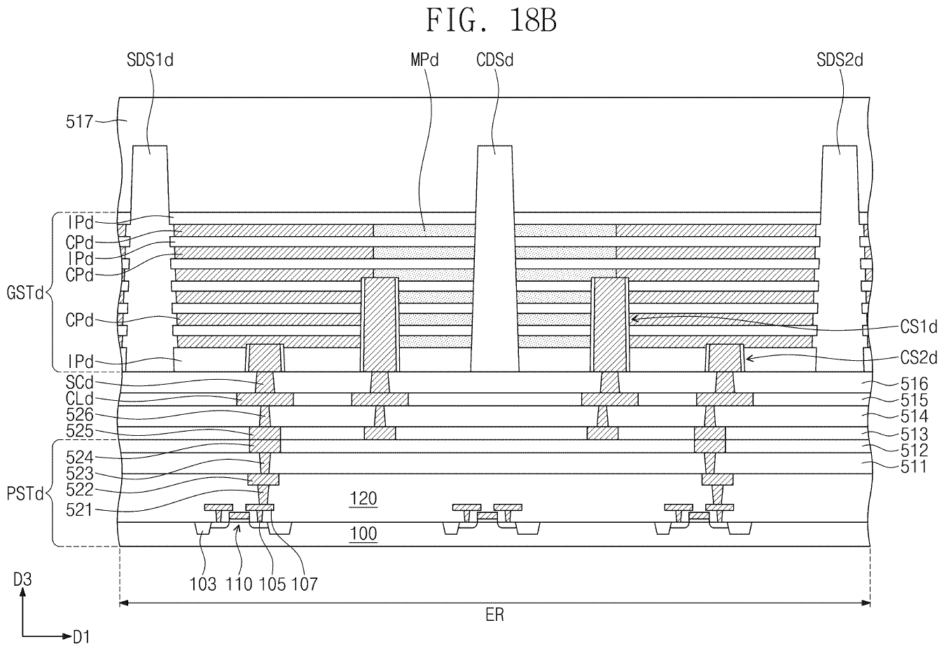

FIGS. 18A and 18B illustrate cross-sectional views showing a semiconductor device according to some example embodiments. Except the following description, a semiconductor device according to FIGS. 18A and 18B may be similar to the semiconductor device according to FIGS. 2A to 2G.

Referring to FIGS. 18A and 18B, a semiconductor device may include a peripheral circuit structure PSTd. The peripheral circuit structure PSTd may include a substrate 100, a peripheral circuit dielectric layer 120, transistors 110, device isolation layers 103, peripheral contacts 105, and peripheral conductive lines 107.

The peripheral circuit structure PSTd may further include a first interlayer dielectric layer 511 on the peripheral circuit dielectric layer 120 and a second interlayer dielectric layer 512 on the first interlayer dielectric layer 511. The first and second interlayer dielectric layers 511 and 512 may include a dielectric material.

The peripheral circuit structure PSTd may further include a first conductive contact 521 on the peripheral conductive line 107, a first conductive pad 522 connected to the first conductive contact 521, a second conductive contact 523 connected to the first conductive pad 522, and a second conductive pad 524 connected to the second conductive contact 523. A conductive material may be included in the first conductive contact 521, the first conductive pad 522, the second conductive contact 523, and the second conductive pad 524.

A third interlayer dielectric layer 513 may be provided on the second interlayer dielectric layer 512. A fourth interlayer dielectric layer 514 may be provided on the third interlayer dielectric layer 513. A fifth interlayer dielectric layer 515 may be provided on the fourth interlayer dielectric layer 514. A sixth interlayer dielectric layer 516 may be provided on the fifth interlayer dielectric layer 515. The third, fourth, fifth, and sixth interlayer dielectric layers 513, 514, 515, and 516 may include a dielectric material.

Third conductive pads 525 may be provided in the third interlayer dielectric layer 513. At least one of the third conductive pads 525 may be bonded to the second conductive pad 524 though, for example, a wafer bonding process. The third interlayer dielectric layer 513 may be bonded to the second interlayer dielectric layer 512 through, for example, a wafer bonding process.

A third conductive contact 526 may be provided which is connected to the third conductive pad 525. The third conductive contact 526 may be connected to a bit line BLd or a conductive line CLd. The third conductive pad 525 and the third conductive contact 526 may include a conductive material.

The sixth interlayer dielectric layer 516 may be provided thereon with a gate stack structure GSTd including dielectric patterns IPd, conductive patterns CPd, and mold patterns MPd. The sixth interlayer dielectric layer 516 may be provided thereon with memory channel structures CHd, first connection contact structures CS1d, and second connection contact structures CS2d. The memory channel structures CHd may include a bit-line pad 185d on the sixth interlayer dielectric layer 516, a dielectric capping layer 189d on the bit-line pad 185d, a channel layer 187d on the dielectric capping layer 189d, and as memory layer 183d on the channel layer 187d.

A bit-line contact BCd may be provided in the sixth interlayer dielectric layer 516 to connect the bit-line pad 185d and the bit line BLd to each other. A conductive line contact SCd may be provided in the sixth interlayer dielectric layer 516 to connect the conductive line CLd to the first connection contact structure CS1d or the second connection contact structure CS2d.

The sixth interlayer dielectric layer 516 may be provided thereon with a first side separation structure SDS1d, a second side separation structure SDS2d, a central separation structure CDSd, and a dielectric structure ISd.

A source structure SSTd may be provided on the first side separation structure SDS1d, the second side separation structure SDS2d, the central separation structure CDSd, and the channel layer 187d of the memory channel structure CHd. The source structure SSTd may include, for example, polysilicon. A cover dielectric layer 517 may be provided on the source structure SSTd and the dielectric structure ISd.

A semiconductor device according to some example embodiments may include a mold pattern to stably support dielectric patterns and to improve stability of the semiconductor device.

Although inventive concepts have been described in connection with the some example embodiments illustrated in the accompanying drawings, it will be understood by one of ordinary skill in the art that variations in form and detail may be made therein without departing from the spirit and essential feature of inventive concepts. The above disclosed embodiments should thus be considered illustrative and not restrictive. Moreover, example embodiments discussed above may be combined with each other if necessary; in particular, example embodiments are not necessarily mutually exclusive with one another.

What is claimed is

1. A semiconductor device, comprising:
a first conductive pattern;
a second conductive pattern spaced apart in a first direction from the first conductive pattern;
a dielectric pattern between the first conductive pattern and the second conductive pattern;
a first mold pattern at a level same as a level of the first conductive pattern;
a second mold pattern at a level same as a level of the second conductive pattern and spaced apart in the first direction from the first mold pattern;
a memory channel structure that penetrates the first conductive pattern and the second conductive pattern;
a first connection contact electrically connected to the first conductive pattern; and
a first connection contact dielectric layer that surrounds the first connection contact,
wherein the dielectric pattern is between the first mold pattern and the second mold pattern, and
wherein the first connection contact and the first connection contact dielectric layer are between the second conductive pattern and the second mold pattern.

2. The semiconductor device of claim 1, wherein
the first connection contact contacts the first conductive pattern and the first mold pattern, and
the first connection contact dielectric layer contacts the first conductive pattern and the first mold pattern.

3. The semiconductor device of claim 2,
wherein the first conductive pattern comprises,
a first surface contacting a bottom surface of the first connection contact, and
a second surface contacting a first sidewall of the first connection contact dielectric layer, and
wherein the first mold pattern comprises,
a first surface contacting the bottom surface of the first connection contact, and
a second surface contacting a second sidewall of the first connection contact dielectric layer.

4. The semiconductor device of claim 3, wherein
the second conductive pattern contacts the first sidewall of the first connection contact dielectric layer, and
the second mold pattern contacts the second sidewall of the first connection contact dielectric layer.

5. The semiconductor device of claim 1, wherein
the first conductive pattern comprises a first overlap part at least partially overlapping the first connection contact,
the first mold pattern comprises a second overlap part at least partially overlapping the first connection contact, and
the first overlap part and the second overlap part contact each other.

6. The semiconductor device of claim 1, further comprising:
a dielectric structure that penetrates the first mold pattern and the second mold pattern,
wherein the second mold pattern comprises a portion between the dielectric structure and the second conductive pattern.

7. The semiconductor device of claim 6, wherein the second conductive pattern comprises:
a first sidewall contacting the dielectric structure;
a second sidewall contacting the second mold pattern; and
a surface contacting the first connection contact dielectric layer.

8. The semiconductor device of claim 1, further comprising:
a second connection contact electrically connected to the second conductive pattern; and
a second connection contact dielectric layer surrounding the second connection contact,
wherein a length in the first direction of the second connection contact is less than a length in the first direction of the first connection contact.

9. A semiconductor device, comprising:
a first side separation structure;
a second side separation structure spaced apart in a first direction from the first side separation structure;
a first conductive pattern, a second conductive pattern, and a mold pattern between the first side separation structure and the second side separation structure;
a dielectric structure between the first side separation structure and the second side separation structure, the dielectric structure penetrating the mold pattern;
a memory channel structure that penetrates the first conductive pattern; and
a first connection contact electrically connected to the first conductive pattern,
wherein the first conductive pattern is between the first side separation structure and the dielectric structure,
wherein the second conductive pattern is between the second side separation structure and the dielectric structure,
wherein the first conductive pattern and the second conductive pattern are spaced apart in the first direction from each other,
wherein the mold pattern contacts the first conductive pattern and the second conductive pattern,
wherein the mold pattern comprises
a first part between the dielectric structure and the first conductive pattern,
a second part between the dielectric structure and the second conductive pattern, and
a third part connecting the first part and the second part to each other.

10. The semiconductor device of claim 9, wherein the dielectric structure is between the first part and the second part.

11. The semiconductor device of claim 9, wherein the first connection contact contacts the first part and the first conductive pattern.

12. The semiconductor device of claim 9, further comprising:
a third conductive pattern spaced apart in a second direction from the first conductive pattern, the second direction crossing the first direction;
a fourth conductive pattern spaced apart in the second direction from the second conductive pattern;
a dielectric pattern between the first and third conductive patterns and between the second and fourth conductive patterns,
wherein the dielectric structure comprises a sidewall contacting a first sidewall of the first conductive pattern, a first sidewall of the third conductive pattern, and a first sidewall of the dielectric pattern,
wherein the first side separation structure comprises,
a base part, and
a protrusion part protruding from the base part,
wherein the base part comprises a sidewall contacting a second sidewall of the dielectric pattern, and
wherein the protrusion part comprises,
a sidewall contacting a second sidewall of the first conductive pattern and
a top surface contacting a bottom surface of the dielectric pattern.

13. The semiconductor device of claim 12, wherein a length in the second direction of the sidewall of the dielectric structure is greater than a length in the second direction of the sidewall of the base part and is greater than a length in the second direction of the sidewall of the protrusion part.

14. The semiconductor device of claim 9, further comprising:
a central separation structure between the first and second side separation structures and connected to the dielectric structure,
wherein the central separation structure is between the first conductive pattern and the second conductive pattern.

15. The semiconductor device of claim 14, wherein a maximum width in the first direction of the central separation structure is greater than a maximum width in the first direction of the dielectric structure.

16. The semiconductor device of claim 14, wherein the dielectric structure comprises:
a first dielectric part contacting the mold pattern;
a second dielectric part contacting the first conductive pattern and the second conductive pattern; and
a third dielectric part contacting the central separation structure,
wherein a maximum width in the first direction of the third dielectric part is less than a maximum width in the first direction of the first dielectric part.

17. The semiconductor device of claim 14, wherein a maximum width in the first direction of the dielectric structure is greater than a maximum width in the first direction of the central separation structure.

18. The semiconductor device of claim 9, wherein the dielectric structure comprises:
a base part; and
a plurality of protrusion parts protruding from the base part,
wherein the base part comprises,
a first dielectric part contacting the mold pattern, and
a second dielectric part spaced apart from the mold pattern, and
wherein the plurality of protrusion parts protrude from the second dielectric part.

19. An electronic system, comprising:
a main board;
a semiconductor device on the main board; and
a controller on the main board and electrically connected to the semiconductor device,
wherein the semiconductor device comprises,
a first side separation structure,
a second side separation structure spaced apart in a first direction from the first side separation structure,
a first conductive pattern, a second conductive pattern, a third conductive pattern, a fourth conductive pattern, a first mold pattern, and a second mold pattern between the first side separation structure and the second side separation structure,
a dielectric pattern between the first and third conductive patterns, between the second and fourth conductive patterns, and between the first and second mold patterns,
a dielectric structure between the first and second side separation structures, the dielectric structure penetrating the first and second mold structures,
a memory channel structure that penetrates the first conductive pattern,
a first connection contact electrically connected to the first conductive pattern,
a first connection contact dielectric layer that surrounds the first connection contact,
a second connection contact electrically connected to the third conductive pattern, and
a second connection contact dielectric layer that surrounds the second connection contact,
wherein the first mold pattern contacts the first conductive pattern and the second conductive pattern,
wherein the second mold pattern contacts the third conductive pattern and the fourth conductive pattern,
wherein the first connection contact contacts the first conductive pattern and the first mold pattern, and
wherein the first connection contact dielectric layer contacts the third conductive pattern and the second mold pattern.

20. The electronic system of claim 19, wherein the second mold pattern comprises:
a first part between the dielectric structure and the first conductive pattern;
a second part between the dielectric structure and the second conductive pattern; and
a third part that connects the first part and the second part to each other,
wherein the first part comprises a sidewall contacting the first conductive pattern,
wherein the second part comprises a sidewall contacting the second conductive pattern, and
wherein a distance in the first direction between the sidewall of the first part and the sidewall of the second part decreases with decreasing distance from the memory channel structure.
